(19) United States
(12) Patent Application Publication
(10) Pub. No.: US 2026/0190711 A1
(43) Pub. Date: Jul. 2, 2026

(54) DISPLAY PANEL AND METHOD FOR REPAIRING THE SAME

(71) Applicant: LG Display Co., Ltd., Seoul (KR)

(72) Inventors: Won Doo KIM, Paju-si (KR); Seung Joon JEON, Paju-si (KR)

(73) Assignee: LG Display Co., Ltd., Seoul (KR)

(21) Appl. No.: 19/403,484

(22) Filed: Nov. 28, 2025

(30) Foreign Application Priority Data
Dec. 27, 2024 (KR) 10-2024-0198423

(51) Int. Cl. H10K 59/131; H10H 29/01; H10H 29/30; H10H 29/32; H10H 29/49; H10K 59/12; H10K 59/121; H10K 59/35; H10K 59/88; H10K 71/00

(52) U.S. Cl. CPC H10K 59/131; H10H 29/012; H10H 29/32; H10H 29/362; H10H 29/49; H10K 59/1201; H10K 59/1213; H10K 59/351; H10K 59/88; H10K 71/861

(57) ABSTRACT

A display panel according to an embodiment of the present disclosure includes a first driving voltage line and a second driving voltage line spaced apart from each other with a pixel therebetween, a plurality of driving voltage connection patterns configured to connect the first and second driving voltage lines, and a plurality of gate lines that intersect the first and second driving voltage lines. The plurality of gate lines may include at least one gate line including an open portion, and the plurality of driving voltage connection patterns may include a repair pattern configured to connect the open portion of the at least one gate line.

### CROSS-REFERENCE TO RELATED APPLICATION

This application claims priority to and the benefit of Korean Patent Application No. 10-2024-0198423, filed Dec. 27, 2024, the disclosure of which is incorporated herein by reference in its entirety.

### BACKGROUND

### Field

The present specification relates to a display panel and a repair method, and more particularly, to a display panel and a repair method capable of repairing wiring defects on a display panel.

### Discussion of Related Art

With the advent of the full-fledged information age, the field of display devices that visually represent electrical information signals has been rapidly advancing.

Representative examples of display devices may include Liquid Crystal Display (LCD) apparatuses, Organic Light Emitting Display (OLED) apparatuses, quantum dot display apparatuses, and the like.

Generally, a display device includes a display panel, and gate driving and source driving circuits that are electrically connected to the display panel and output gate signals and data signals. The display panel may include a display area including a plurality of pixels and a peripheral area in which the gate driving circuit and the source driving circuit are arranged around the display area. Here, components such as various types of transistors, light-emitting elements, data lines, gate lines, driving voltage lines, reference voltage lines, and common voltage lines may be formed in the display area.

The components of the display area may be formed on a substrate through multiple thin-film deposition and etching processes. When a defect occurs during the etching process of the display panel, wire defects such as open portions or disconnections in the gate lines, data lines, reference voltage lines, and the like may occur.

### SUMMARY

A display panel and a repair method according to an example embodiment may repair a wire defect by using a line other than a line in which the wire defect has occurred.

The aspects of the present specification are not limited to the foregoing aspects, and additional aspects, which are not mentioned herein, will be described in the following description or be apparent to those skilled in the art from the following description.

To achieve these and other advantages and in accordance with an aspect of the present specification, as embodied and broadly described herein, a display panel according to an example embodiment of the present specification may include first and second driving voltage lines spaced apart from each other with a pixel therebetween, a plurality of driving voltage connection patterns configured to connect the first and second driving voltage lines, and a plurality of gate lines that intersect the first and second driving voltage lines. Here, the plurality of gate lines may include at least one gate line including an open portion, and the plurality of driving voltage connection patterns may include a repair pattern configured to connect the open portion of the at least one gate line.

In another aspect, a method for repairing a display panel according to an example embodiment of the present specification includes: a first operation of forming a first driving voltage line and a second driving voltage line spaced apart from each other with a pixel therebetween and a plurality of driving voltage connection patterns configured to connect the first and second driving voltage lines; a second operation of forming a plurality of gate lines that intersect the first and second driving voltage lines, the plurality of gate lines including at least one gate line including an open portion; and a third operation of separating at least one of the plurality of driving voltage connection patterns from the first and second driving voltage lines to thereby form a repair pattern configured to connect the open portion of the at least one gate line.

A repair method according to an example embodiment may include a first operation of forming a first driving voltage line and a second driving voltage line spaced apart from each other with a pixel therebetween and a plurality of driving voltage connection patterns configured to connect the first and second driving voltage lines; a second operation of forming a plurality of gate lines that intersect the first and second driving voltage lines, the plurality of gate lines including at least one gate line including an open portion; and a third operation of separating at least one of the plurality of driving voltage connection patterns from the first and second driving voltage lines to thereby form a repair pattern configured to connect two ends of the at least one gate line disconnected by the open portion.

A display panel according to another example embodiment of the present disclosure may include a first driving voltage line and a second driving voltage line spaced apart from each other with at least one pixel therebetween; a plurality of driving voltage connection patterns configured to connect the first and second driving voltage lines; and a plurality of gate lines that intersect the first and second driving voltage lines. Here, the number of gate lines disposed between every two adjacent driving voltage connection patterns of the plurality of driving voltage connection patterns may be 2 or less.

The display panel and the repair method according to one or more example embodiments of the present specification may have the effect of readily repairing defects of various lines by using a driving voltage line in the form of a mesh.

The effects of the present specification are not limited to the effects mentioned above, and other effects not mentioned will be apparent from the following description to one having ordinary skill in the art to which the technical ideas of the present specification belong.

### BRIEF DESCRIPTION OF THE DRAWINGS

The accompanying drawings, which are included to provide a further understanding of the present specification and are incorporated in and constitute a part of this application, illustrate example embodiments of the present specification and together with the description serve to explain various principles of the specification. In the drawings:

FIG. 1 is a schematic plan view of a display panel according to one or more example embodiments of the present specification;

FIG. 2 is a circuit diagram of a sub-pixel circuit according to one or more example embodiments;

FIG. 3 is a plan view illustrating a normal wire state of a display panel according to an example embodiment of the present specification;

FIG. 4 is a circuit schematic illustrating a normal wire state of a display panel according to an example embodiment of the present specification;

FIG. 5A is an enlarged plan view illustrating the circuit part of FIG. 3;

FIG. 5B is a plan view illustrating a driving voltage connection pattern according to an example embodiment;

FIG. 6A is a view illustrating defective wire state 1 of a gate line according to an example embodiment;

FIG. 6B is a view illustrating defective wire state 2 of a gate line according to an example embodiment;

FIG. 7A is a plan view of a display panel according to an example embodiment of the present specification;

FIG. 7B is a plan view illustrating the signal path of a repaired gate line according to an example embodiment;

FIGS. 8A to 8D are plan views illustrating a repair process according to an example embodiment;

FIGS. 9A to 9D are circuit schematics illustrating a repair process according to an example embodiment;

FIGS. 10A to 10C are cross-sectional views illustrating a repair process according to an example embodiment;

FIG. 11 is a plan view illustrating a defective pixel according to an example embodiment;

FIG. 12 is a circuit schematic illustrating a defective pixel according to an example embodiment;

FIG. 13 is a view schematically illustrating a pixel repair method according to an example embodiment;

FIGS. 14A to 14C are plan views illustrating a pixel repair process according to an example embodiment;

FIGS. 15A to 15C are circuit schematics illustrating a pixel repair process according to an example embodiment; and

FIGS. 16A to 16C are cross-sectional views illustrating a pixel repair process according to an example embodiment.

### DETAILED DESCRIPTION

The advantages and features of the present disclosure, and methods for achieving them will become apparent from the example embodiments described below in detail in conjunction with the accompanying drawings. However, the present disclosure is not limited to the example embodiments disclosed herein, but may be implemented in various different forms. The example embodiments are provided to make the disclosure of the present disclosure more complete and to enable those skilled in the art to comprehend the scope of the present disclosure more fully.

The shapes, sizes, proportions, angles, numbers, and the like of elements shown in the drawings to illustrate example embodiments of the present disclosure are merely illustrative and are not intended to be limiting. Identical reference numerals may designate identical components throughout the description. Further, in describing the present disclosure, detailed descriptions of well-known technologies may be omitted so as not to obscure aspects or features of the present disclosure.

Terms such as “comprising,” “including,” “having,” and “consisting of” as used herein are generally intended to allow for the addition of other components, unless the terms are used with a more specific term like “only.” References to components of a singular noun include the plural of that noun, and vice versa, unless specifically stated otherwise.

In the description of components, they are to be interpreted to include margins of error even where not explicitly so stated.

Where the positional relationship is described, for example, if the positional relationship of the two parts is described as “on the top,” “above,” “below,” “next to,” etc., one or more other parts may be located between the two parts unless a more specific term like “directly” is used.

Where an element or layer is described as disposed “on” another element or layer, the element or layer may be disposed directly on another element or layer or may be indirectly disposed on another element or layer with still another element or layer therebetween.

Terms like “first,” “second,” etc., are used to describe various components, but these components are not limited by these terms. These terms are used only to refer to one component separately from another. Therefore, the first component referred to below may be a second component, and vice versa, within the technical spirit of the present disclosure.

Like reference numerals generally denote like elements throughout the specification.

The size and thickness of each component illustrated in the drawings are shown for convenience of description, and the present disclosure is not necessarily limited to the size and thickness of the component illustrated.

The features of various embodiments of the present disclosure can be partially or entirely bonded to or combined with each other. The embodiments can be interoperated and performed in various ways technically and can be carried out independently of or in association with each other.

As used herein, “a device” may include a display apparatus, such as a liquid crystal module (LCM) or an organic light emitting display (OLED) module, which includes a display panel and a driver for driving the display panel. It may also include a set electronic device or a set device, such as a laptop computer, a television set, a computer monitor, a vehicle or an automotive device, or an equipment device including another form of vehicle, and a mobile electronic device, such as a smart phone or an electronic pad and the like, which is a complete product or finished product including LCMs, OLED modules, and the like.

Accordingly, the apparatus or device as described herein may include a display apparatus itself, such as an LCM or OLED module, and an application product, as well as a set device, an end user device that includes the LCM or the OLED module.

Furthermore, in some embodiments, the LCM and OLED module including the display panel and the driver may be expressed as a “display apparatus,” the electronic device may be expressed as a finished product including the LCM and OLED module that may be expressed as a “set device.” For example, a display apparatus may include a liquid crystal display (LCD) panel or an organic light emitting display (OLED) panel, and a source PCB (printed circuit board) which is a control part for driving the display panel. The set device may further include a set PCB, which is a set control part electrically connected to the source PCB to drive the entire set device.

The display panel used in embodiments of the present disclosure may be any type of display panel, including, but not limited to, a liquid crystal display panel, an organic light emitting diode (OLED) display panel, and an electroluminescent display panel. The display panel applicable to the display apparatus according to embodiments of the present disclosure is not limited to the shape or size of the display panel.

Each of the features of the various embodiments described herein may be coupled or combined with one another in whole or in part, and may be technologically interlocked and operated in various ways, and each of the embodiments may be carried out independently or in conjunction with one another.

Hereinafter, various example embodiments of the present disclosure will be described in detail with reference to the accompanying drawings. The dimensions of the components shown in the drawings are for illustrative purposes only and are not necessarily to scale with the actual components shown in the drawings.

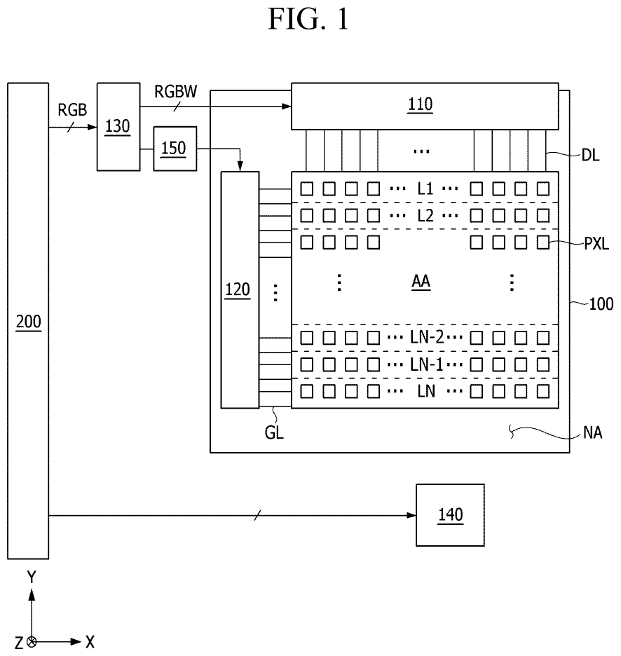

FIG. 1 is a plan view for a display panel of the present specification according to one or more example embodiments.

As shown in FIG. 1, a horizontal direction X and a vertical direction Y of a display panel 100 may be a length direction and a width direction of the display panel 100, respectively. Further, the horizontal direction X and the vertical direction Y of the display panel 100 may also be represented by a row direction and a column direction, respectively. A thickness direction Z may refer to a direction perpendicular to a plane defined by the horizontal direction X and the vertical direction Y of the display panel 100. The display panel 100 may have a cross-section in the thickness direction Z.

As shown in FIG. 1, the display panel 100 according to more or more example embodiments of the present disclosure may include a display panel driving circuit for writing pixel data to pixels, and a power supply 140 for generating power for driving the pixels and the display panel driving circuit.

A display area AA of the display panel 100 may include a pixel array for displaying an input image thereon. The pixel array may include a plurality of data lines DL, a plurality of gate lines GL crossing the data lines DL, and pixels arranged in a matrix form. The display panel 100 may include power lines commonly connected to the pixels. The power lines may be commonly connected to constant voltage nodes of pixel circuits and supply constant voltages for driving the pixels PXL. The power lines may be implemented as striped or mesh wires to be connected in common to the pixels of the display panel 100.

Each of the pixels PXL may include a first sub-pixel, a second sub-pixel, a third sub-pixel, and a fourth sub-pixel of different colors for color implementation. The color arrangement of the sub-pixels may be changed. The first sub-pixel may be, but is not limited to, a blue (B) sub-pixel, the second sub-pixel may be a green (G) sub-pixel, the third sub-pixel may be a red (R) sub-pixel, and the fourth sub-pixel may be a white (W) sub-pixel. In an exemplary embodiment, each sub-pixel may display one color among red, green and blue. In another exemplary embodiment, each sub-pixel may display one color among cyan, magenta and yellow.

Each of the sub-pixels may include a pixel circuit to drive a light-emitting element. Each of the pixel circuits may be connected to the data lines, the gate lines, and the power lines. Each sub-pixel may be divided into a circuit area and a light-emitting area. The pixel circuit may be located in the circuit area. The light-emitting area may be the area from which light is emitted by a light-emitting element electrically connected to the pixel circuit.

The pixel array may include a plurality of pixel lines L1 to LN. Each of the pixel lines L1 to LN may include one line of pixels arranged along the X-axis direction in the pixel array of the display panel 100. The pixels arranged in one pixel line may share the gate lines GL. The sub-pixels arranged in the column direction (Y) along a data line direction may share the same data line DL. One horizontal period is a time obtained by dividing one frame period by the total number of the pixel lines L1 to LN.

The power supply 140 outputs voltages for driving the pixels and the display panel driving circuit of the display panel 100 by using a direct current (DC)-to-direct current DC) converter (DC-DC converter). The DC-DC converter may include a charge pump, a regulator, a buck converter, a boost converter, and the like.

The display panel driving circuit writes the pixel data of an input image to the pixels of the display panel 100 under the control of a timing controller 130. The display panel driving circuit includes a data driver 110 and a gate driver 120, and other circuit components.

The display panel driving circuit may drive the pixels with double rate driving (DRD). In a DRD-driven display panel, the data lines DL are connected to neighboring sub-pixels on the left and right, reducing the number of channels in the data driver 110 and the number of data lines DL, which is advantageous for ensuring the aperture ration of the pixels.

In one or more aspects, in order to further provide a touch sensing function, as well as an image display function, the display panel driving circuit may further include at least one touch sensor, and a touch sensing circuit capable of detecting the occurrence of a touch event by a touch object such as a finger, a pen, or the like, or detecting a corresponding touch location (or touch coordinates), by sensing the touch sensor, and the like. The display panel driving circuit may further include a touch sensor driver for driving the touch sensors. The touch sensor driver is omitted from FIG. 1. The data driver 110 and the touch sensor driver may be integrated into one source drive IC (Integrated Circuit), but is not limited thereto.

The data driver 110 may receive pixel data of the input image received as a digital signal from the timing controller 130 and output a data voltage. The data driver 110 may output the data voltage by converting the pixel data of the input image into a gamma compensated voltage every frame period using a digital-to-analog converter (DAC). The data voltage may be outputted from each of the channels of the data driver 110 through an output buffer.

The gate driver 120 may be formed in the display panel 100 together with a TFT array of the pixel array and the wires. The gate driver 120 may be located on a non-display area NA of the display panel 100, or at least some of the gate driver may be located within a display area AA in which an input image is reproduced.

In one or more aspects, the gate driver 120 may be connected to the display panel 100 by the tape-automated-bonding (TAB) technique, or connected to a conductive pad such as a bonding pad of the display panel 100 by the chip-on-glass (COG) technique or the chip-on-panel (COP) technique, or connected to the display panel 110 by the chip-on-film (COF) technique. In one or more aspects, the gate driver 120 may be disposed in the non-display area NA of the display panel 100 by a gate-in-panel (GIP) technique, without being limited thereto. Alternatively, the gate driver 120 may be disposed in the display area AA of the display panel 100.

The gate driver 120 may be located in the non-display areas NA on both sides of the display panel 100 with the display area AA of the display panel interposed therebetween, and it may supply gate pulses from both sides of the gate lines GL in a double feeding method. In another example embodiment, the gate driver 120 may be located in at least one of the left and right non-display areas NA of the display panel 100 and may supply gate signals to the gate lines GL in a single feeding method. The gate driver 120 sequentially outputs pulses of the gate signals (hereinafter referred to as “gate pulses”) to the gate lines 103 under the control of the timing controller 130. The gate driver 120 may shift the gate pulses using a shift register to sequentially supply the gate pulses to the gate lines GL. The gate driver 120 may include one or more shift registers that output the pulses of the gate signals.

The timing controller 130 receives digital video data of the input image and a timing signal synchronized with the digital video data from the host system 200. The timing signal may include a vertical synchronization signal, a horizontal synchronization signal, a clock and a data enable signal. A vertical period and a horizontal period may be known by counting the data enable signal, and thus the vertical synchronization signal and the horizontal synchronization signal may be omitted. The data enable signal has a cycle of one horizontal period (1H). The timing controller 130 generates a data timing control signal for controlling the operation timing of the data driver 110 and a gate timing control signal for controlling the operation timing of the gate driver 120 based on the timing signals signal received from the host system 200.

The timing controller 130 may add white color data to the three primary colors of pixel data RGB input from the host system and convert it to four sub-color data RGBW for transmission to the data driver 110. Any known color conversion algorithm may be used to convert the three primary colors of pixel data RGB into four sub color data RGBW including the white color data.

For example, the timing controller 130 may convert the first pixel data to four sub-color data RGBW by generating the W data of the first pixel data based on the minimum grayscale value among the R data, G data, and B data of the first pixel data received as data of the input image. Further, the timing controller 130 may convert the second pixel data to four sub-color data RGBW by generating the W data of the second pixel data based on the minimum grayscale value among the R data, G data, and B data of the second pixel data received as data of the input image.

For each of the first pixel data and the second pixel data, the grayscale values of the R, G, and B data may be lowered by the W data. Here, R data is data to be written to the red sub-pixel, and G data is data to be written to the green sub-pixel. B data is data to be written in the blue sub-pixel, and data W is data to be written in the white sub-pixel.

The level shifter 150 may receive the gate timing control signal from the timing controller 130 and generate a start pulse and a shift clock to provide them to the gate driver 120. The start pulse and the shift clock output from the level shifter 150 swing between the gate-high voltage and the gate-low voltage.

The host system 200 may include a main board of any of a television system, a set-top box, a navigation system, a personal computer (PC), an in-vehicle system, a mobile terminal, or a wearable terminal. The host system may scale an image signal from a video source to match the resolution of the display panel 100, and may transmit it to the timing controller 130 together with the timing signal.

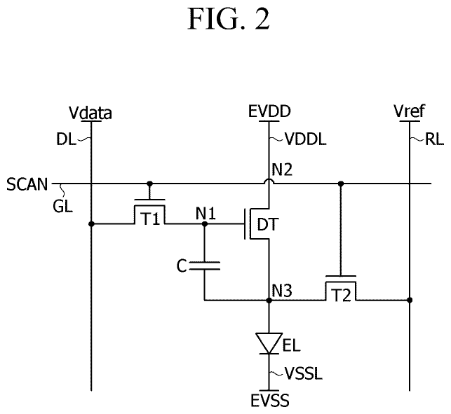

FIG. 2 is a circuit diagram for a sub-pixel circuit according to one or more example embodiments.

As shown in FIG. 2, a circuit for each of sub-pixels PXL (hereinafter referred to as a sub-pixel circuit) may be connected to a data line DL to which a data voltage Vdata of pixel data is applied, a gate line GL to which a gate pulse SCAN is applied, a driving voltage line VDDL to which a pixel driving voltage EVDD is applied, a low-potential voltage line VSSL to which a low-potential voltage EVSS is applied, and a reference voltage line RL to which a reference voltage Vref is applied.

Each sub-pixel circuit may include a light-emitting element EL, a plurality of transistors DT, T1, and T2, and a capacitor C. However, in the display panel described herein, the sub-pixel circuit configuration is not limited thereto. For example, 4T1C, 5T1C, 3T2C, 4T2C, 5T2C, 6T2C, 7T1C, 7T2C, 8T2C structures, etc. are also possible. And more or less transistors and capacitors could be included.

The light-emitting element may be an organic light-emitting diode (OLED) or an inorganic light-emitting element such as micro LED. The light-emitting element EL may include, but not limited to, a red light-emitting element, a green light-emitting element, and a blue light-emitting element. An anode electrode of the light-emitting element EL may be electrically connected to the driving element DT and disposed in its corresponding light-emitting area in each pixel. The light-emitting element EL is driven and emits light when a current from the driving element DT is generated, and the light is emitted to the outside of the display panel through the light-emitting area.

The driving element DT may generate a current according to the gate-source voltage to drive the light-emitting element EL. The driving element DT includes a gate electrode connected to a first node N1, a first electrode connected to a second node N2, and a second electrode connected to a third node N3. A capacitor C is connected between the first node N1 and the third node N3. The second node N2 is connected to the driving voltage line VDDL. The third node N3 is connected to an anode electrode of the light-emitting element EL. A cathode electrode of the light-emitting element EL is connected to a low-potential voltage line VSSL to which the low-potential voltage EVSS is applied.

A first switch element T1 is connected between the data line DL and the first node N1. The first switch element T1 is turned on in response to the gate pulse SCAN. When the first switch element T1 is turned on, the data voltage Vdata of the pixel data is applied to the first node N1, thereby writing the pixel data to the sub-pixel. The first switch element T1 may include a gate electrode connected to the gate line GL, a first electrode connected to the data line DL, and a second electrode connected to the first node N1.

The second switch element T2 is connected between the third node N3 and the reference voltage line RL. The second switch element T2 is turned on in response to the gate pulse SCAN. When the second switch element T2 is turned on, the third node N3 is connected to the reference voltage line RL. The second switch element T2 may include a gate electrode connected to the gate line GL, a first electrode connected to the third node N3, and a second electrode connected to the reference voltage line RL.

The first electrode may be one of the source electrode and the drain electrode, and the second electrode may be the other of the source electrode and the drain electrode. In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

The driving element DT should have uniform electrical characteristics across all sub-pixels; however, due to process deviations and device characteristic deviations, differences in electrical characteristics may exist between sub-pixels, and these differences may increase as the sub-pixel driving time elapses. To compensate for these deviations in the electrical characteristics of the driving element DT, an external compensation circuit may be applied to the display panel driving circuit.

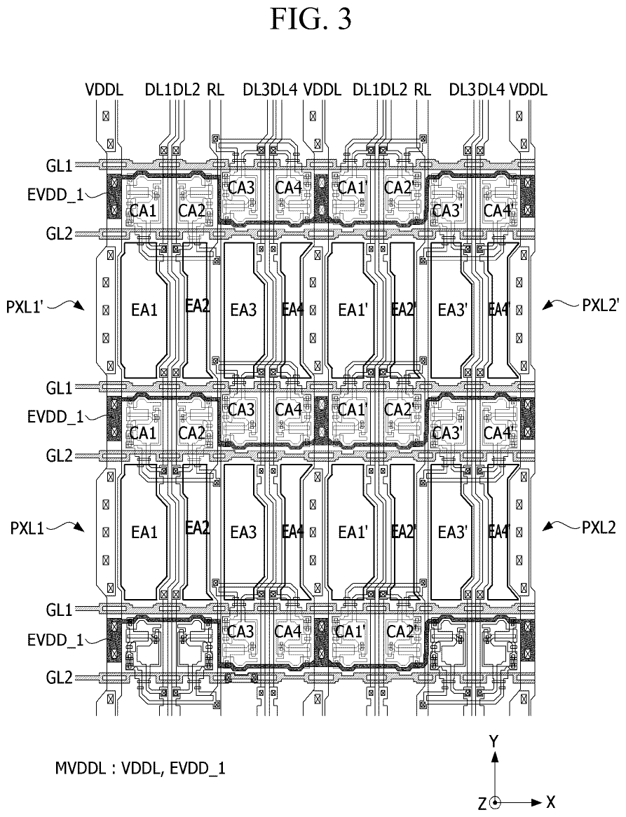

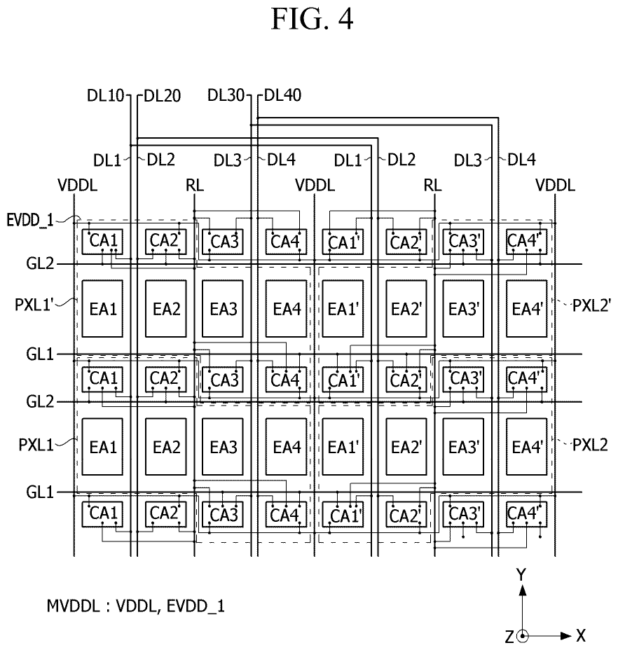

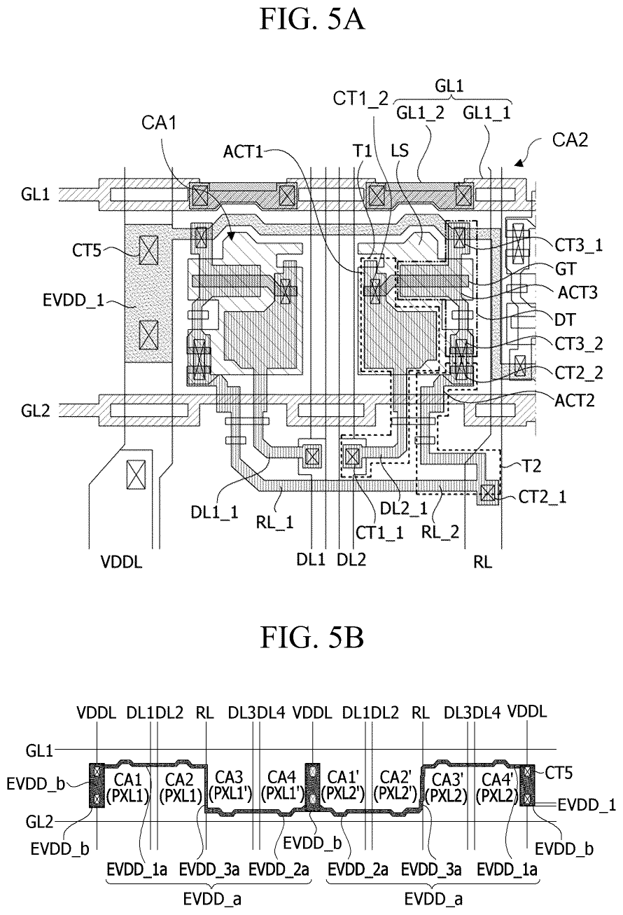

FIG. 3 is a plan view illustrating a normal wire state of a display panel according to an example embodiment of the present specification. FIG. 4 is a circuit schematic illustrating a normal wire state of a display panel according to an example embodiment of the present specification. FIG. 5A is an enlarged plan view illustrating the circuit parts of FIG. 3, and FIG. 5B is a plan view illustrating a driving voltage connection pattern according to an example embodiment.

As shown in FIGS. 3 and 4, the display panel according to an example embodiment may include a plurality of pixels PXL1, PXL1′, PXL2, and PXL2′, and may include driving voltage lines MVDDL, reference voltage lines RL, data lines DL1, DL2, DL3, and DL4, and gate lines GL1 and GL2 configured to drive the plurality of pixels PXL1, PXL1′, PXL2, and PXL2′. The horizontal direction X of the display panel 100 may be aligned with the gate lines GL1 and GL2, and the vertical direction Y thereof may be aligned with the driving voltage lines VDDL, the reference voltage lines RL, and the data lines DL1, DL2, DL3, and DL4.

The plurality of pixels PXL (PXL1, PXL1′, PXL2, and PXL2′) may include a first pixel PXL1, a first prime pixel PXL1′, a second pixel PXL2, and a second prime pixel PXL2′.

The first pixel PXL1 and first prime pixel PXL1′ having the same structure may be arranged in a repeating pattern along the vertical direction Y. Here, some circuit parts of the first and first prime pixels PXL1 and PXL1′ may be aligned with each other in the horizontal direction X. For example, the first and second circuit parts CA1 and CA2 of the first pixel PXL1 may be aligned with the third and fourth circuit parts CA3 and CA4 of the first prime pixel PXL1′ in the horizontal direction X.

The second pixel PXL2 and second prime pixel PXL2′ having the same structure may be arranged in a repeating pattern along the vertical direction Y. Here, some circuit parts of the second and second prime pixels PXL2 and PXL2′ may be aligned with each other in the horizontal direction X. For example, the first prime and second prime circuit parts CA1′ and CA2′ of the second pixel PXL2 may be aligned with the third and fourth prime circuit parts CA3′ and CA4′ of the second prime pixel PXL2′ in the horizontal direction X.

The first pixel PXL1 and the second pixel PXL2 may be arranged in a repeating pattern along the horizontal direction X. Also, the first prime pixel PXL1′ and the second prime pixel PXL2′ may be arranged in a repeating pattern along the horizontal direction X. Two pixels arranged in a repeating pattern along the horizontal direction X will be described below by taking the first and second pixels PXL1 and PXL2 as an example.

The first to fourth emission part EA (EA1, EA2, EA3, EA4, EA1′, EA2′, EA3′, and EA4′) of the first pixel PXL1 and second pixel PXL2 may be sequentially arranged in the horizontal direction X. For example, with respect to the driving voltage line VDDL between the first and second pixels PXL1 and PXL2, the first to fourth emission part EA1, EA2, EA3, and EA4 of the first pixel PXL1 may be sequentially arranged from the left on the left side, and the first prime to fourth prime emission part EA1′, EA2′, EA3′, and EA4′ of the second pixel PXL2 may be sequentially arranged from the left on the right side.

For example, the first to fourth emission part EA1, EA2, EA3, and EA4 of the first pixel PXL1 may be arranged on the left side of the driving voltage line VDDL, and the first prime to fourth prime emission part EA1′, EA2′, EA3′, and EA4′ of the second pixel PXL2 may be arranged on the right side of the driving voltage line VDDL, but is not limited thereto.

In contrast, the first to fourth circuit parts CA (CA1, CA2, CA3, CA4, CA1′, CA2′, CA3′, and CA4′) of the first pixel PXL1 and second pixel PXL2 may be arranged in a symmetrical form based on the vertical direction Y. With respect to the driving voltage line VDDL arranged between the first and second pixels PXL1 and PXL2, the first to fourth circuit parts CA1, CA2, CA3, and CA4 of the first pixel PXL1 arranged on the left side may be symmetrical to the first to fourth circuit parts CA1′, CA2′, CA3′, and CA4′ of the second pixel PXL2 arranged on the right side.

For example, the first and second circuit parts CA1 and CA2 of the first pixel PXL1 may be arranged at the upper side of the corresponding first and second emission part EA1 and EA2, respectively, and the third and fourth circuit parts CA3 and CA4 of the first pixel PXL1 may be arranged at the lower side of the corresponding third and fourth emission part EA3 and EA4, respectively. For example, the first prime and second prime circuit parts CA1′ and CA2′ of the second pixel PXL2 may be arranged at the lower side of the corresponding first prime and second prime emission part EA1′ and EA2′, respectively, and the third prime and fourth prime circuit parts CA3′ and CA4′ of the second pixel PXL2 may be arranged at the upper side of the corresponding third prime and fourth prime emission part EA3′ and EA4′, respectively. However, the arrangement structure of the plurality of pixels is illustrative, and embodiments of the present specification are not limited thereto.

Each of the plurality of pixels PXL1 and PXL2 may include one or more sub-pixels. For example, the first pixel PXL1 may include a first sub-pixel including a first emitting component EA1 and a first circuit part CA1, a second sub-pixel including a second emitting component EA2 and a second circuit part CA2, a third sub-pixel including a third emitting component EA3 and a third circuit part CA3, and a fourth sub-pixel including a fourth emitting component EA4 and a fourth circuit part CA4.

For example, the second pixel PXL2 may include a first sub-pixel including a first prime emitting component EA1′ and a first prime circuit part CA1′, a second sub-pixel including a second prime emitting component EA2′ and a second prime circuit part CA2′, a third sub-pixel including a third prime emitting component EA3′ and a third prime circuit part CA3′, and a fourth sub-pixel including a fourth emitting component EA4′ and a fourth prime circuit part CA4′.

Each of the plurality of pixels PXL1 and PXL2 may include sub-pixels that emit different colors. For example, the plurality of pixels PXL1 and PXL2 may include a red sub-pixel, a green sub-pixel, a blue sub-pixel, and a white sub-pixel. For example, the red sub-pixel may be the first sub-pixel, the green sub-pixel may be the second sub-pixel, the white sub-pixel may be the third sub-pixel, and the blue sub-pixel may be the fourth sub-pixel.

As shown in FIG. 3 and FIG. 4 together, the first and first prime emission part EA1 and EA1′ may emit red light as the first sub-pixels, the second and second prime emission part EA2 and EA2′ may emit green light as the second sub-pixels, the third and third prime emission part EA3 and EA3′ may emit white light as the third sub-pixels, and the fourth and fourth prime emission part EA4 and EA4′ may emit blue light as the fourth sub-pixels. However, the types of the plurality of sub-pixels are illustrative, and embodiments of the present specification are not limited thereto.

Each sub-pixel may be connected to the data line DL, the gate line GL, the driving voltage line MVDDL, and the reference voltage line RL.

The data lines DL1, DL2, DL3, and DL4 branch from the corresponding main data lines DL10, DL20, DL30, and DL40, respectively, to reach the two neighboring pixels PXL1 and PXL2, and may be driven in a DRD manner. For example, the data lines DL1, DL2, DL3, and DL4 branch from the corresponding main data lines DL10, DL20, DL30, and DL40, respectively, to reach corresponding sub-pixels of the two neighboring pixels PXL1 and PXL2.

For example, the first main data line DL10 may branch into the first data lines DL1 to be connected to the first sub-pixel of each of the first pixel PXL1 and second pixel PXL2, the second main data line DL20 may branch into the second data lines DL2 to be connected to the second sub-pixel of each of the first pixel PXL1 and second pixel PXL2, and the third main data line DL30 may branch into the third data lines DL3 to be connected to the third sub-pixel of each of the first pixel PXL1 and second pixel PXL2, and the fourth main data line DL40 may branch into the fourth data lines DL4 to be connected to the fourth sub-pixel of each of the first pixel PXL1 and second pixel PXL2.

Here, each of the first to fourth data lines DL1, DL2, DL3, and DL4 may form branch lines extending therefrom to the corresponding sub-pixels. Accordingly, the first to fourth data lines DL1, DL2, DL3, and DL4 may supply data signals to the corresponding sub-pixels through the branch lines.

The two data lines branching from the main data line may have branch lines arranged in different directions for two different circuit parts arranged in the same column. For example, when a single main data line branches into two data lines, one data line may have branch lines arranged at the upper side of a circuit part, and the other data line may have branch lines arranged at the lower side of another circuit part.

The gate lines GL (GL1 and GL2) may include a first gate line GL1 and a second gate line GL2. The first and second gate lines may be arranged in a repeating pattern along the vertical direction Y. The first and second gate lines GL1 and GL2 adjacent to each other may be arranged at the upper and lower sides, respectively, of the circuit parts CA in the vertical direction Y.

For example, the first gate line GL1 may be arranged at the upper side of the circuit part CA with respect to the vertical direction Y, and the second gate line GL2 may be arranged at the lower side of the circuit part CA with respect to the vertical direction Y. The first and second gate lines GL1 and GL2 may respectively correspond to two data lines branching from the main data line. Accordingly, although the main data line supplies the same signal to the two data lines, the two data lines may respectively intersect the first and second gate lines that are different from each other.

For example, the first gate line GL1 may supply a signal to the third and fourth circuit parts CA3 and CA4 of the first pixel PXL1 and supply a signal to the first prime and second prime circuit parts CA1′ and CA2′ of the second pixel PXL2. For example, the second gate line GL2 may supply a signal to the first and second circuit parts CA1 and CA2 of the first pixel PXL1 and supply a signal to the third prime and fourth prime circuit parts CA3′ and CA4′ of the second pixel PXL2.

As one example, for the first pixel PXL1, the first and second sub-pixels may be formed at the intersection of the second gate line GL2 and the data lines, and the third and fourth sub-pixels may be formed at the intersection of the first gate line GL1 and the data lines. For the second pixel PXL2, the first and second sub-pixels may be formed at the intersection of the first gate line GL1 and the data lines, and the third and fourth sub-pixels may be formed at the intersection of the second gate line GL2 and the data lines, but is not limited thereto.

In this case, for the first pixel PXL1, the first sub-pixel may be formed at the intersection of the second gate line GL2 and the first data line DL1, the second sub-pixel may be formed at the intersection of the second gate line GL2 and the second data line DL2, the third sub-pixel may be formed at the intersection of the first gate line GL1 and the third data line DL3, and the fourth sub-pixel may be formed at the intersection of the first gate line GL1 and the fourth data line DL4.

For the second pixel PXL2, the first sub-pixel may be formed at the intersection of the first gate line GL1 and the first data line DL1, the second sub-pixel may be formed at the intersection of the first gate line GL1 and the second data line DL2, the third sub-pixel may be formed at the intersection of the second gate line GL2 and the third data line DL3, and the fourth sub-pixel may be formed at the intersection of the second gate line GL2 and the fourth data line DL4.

In other words, in the DRD method, the first and second pixels PXL1 and PXL2 are supplied with signals of the same main data lines DL10, DL20, DL30, and DL40, but may be individually driven by the different gate lines GL1 and GL2.

For example, the first sub-pixel of the first pixel PXL1 may be driven by the first data line DL1, which branches to the left from the first main data line DL10, and the second gate line GL2, and the first sub-pixel of the second pixel PXL2 may be driven by the first data line DL1, which branches to the right from the first main data line DL10, and the first gate line GL1. For example, the second sub-pixel of the first pixel PXL1 may be driven by the second data line DL2, which branches to the left from the second main data line DL20, and the second gate line GL2, and the second sub-pixel of the second pixel PXL2 may be driven by the second data line DL2, which branches to the right from the second main data line DL20, and the first gate line GL1.

For example, the third sub-pixel of the first pixel PXL1 may be driven by the third data line DL3, which branches to the left from the third main data line DL30, and the first gate line GL1, and the third sub-pixel of the second pixel PXL2 may be driven by the third data line DL3, which branches to the right from the third main data line DL30, and the second gate line GL2. For example, the fourth sub-pixel of the first pixel PXL1 may be driven by the fourth data line DL4, which branches to the left from the fourth main data line DL40, and the first gate line GL1, and the fourth sub-pixel of the second pixel PXL2 may be driven by the fourth data line DL4, which branches to the right from the fourth main data line DL40, and the second gate line GL2.

As shown in FIG. 5B, the driving voltage lines MVDDL according to an example embodiment of the present specification may include a plurality of driving voltage lines VDDL arranged in the vertical direction Y and a plurality of driving voltage connection patterns EVDD_1 configured to connect the plurality of driving voltage lines VDDL. The driving voltage lines VDDL and the driving voltage connection patterns EVDD_1 may form a mesh pattern by intersecting each other. However, the display panel of the present specification is not limited thereto. For example, the driving voltage lines VDDL and the driving voltage connection patterns EVDD_1 may be integrally formed on the same layer. For example, referring to FIGS. 3 and 5B, the number of gate lines disposed between every two adjacent driving voltage connection patterns of the plurality of driving voltage connection patterns EVDD_1 may be 2 or less, but is not limited thereto.

Each of the driving voltage lines VDDL may be arranged between each pair of the pixels PXL1 or PXL2. In other words, the driving voltage lines VDDL may be spaced apart from each other with the first pixels PXL1 or the second pixels PXL2 therebetween.

The driving voltage connection patterns EVDD_1 may connect the driving voltage lines VDDL. Each of the driving voltage connection patterns EVDD_1 may be arranged between each pair of the first and second gate lines GL1 and GL2 adjacent to each other. Each of the driving voltage connection patterns EVDD_1 may have a bilaterally symmetrical form with respect to the driving voltage line VDDL arranged between the first and second pixels PXL1 and PXL2.

Each of the driving voltage connection patterns EVDD_1 may include connection lines EVDD_a and overlapping portions EVDD_b. Each of the driving voltage connection patterns EVDD_1 may be arranged such that the connection line EVDD_a and the overlapping portion EVDD_b are alternated. The connection lines EVDD_a and the overlapping portions EVDD_b may be integrally formed. The overlapping portions EVDD_b are regions that overlap the driving voltage lines VDDL and may contact the driving voltage lines VDDL. For example, each overlapping portion EVDD_b and each driving voltage line VDDL may contact each other at a fifth contact portion CT5.

Each of the connection lines EVDD_a may be arranged between the overlapping portions EVDD_b by extending from the overlapping portions EVDD_b. That is, the connection line EVDD_a may be arranged between each pair of the driving voltage lines VDDL. The connection line EVDD_a may include a first connection line EVDD_1a, a second connection line EVDD_2a, and a third connection line EVDD_3a arranged between the first and second connection lines EVDD_1a and EVDD_2a. For example, the first connection line EVDD_1a, the second connection line EVDD_2a, and the third connection line EVDD_3a may be arranged between the overlapping portions EVDD_b.

The first and second connection lines EVDD_1a and EVDD_2a may extend from the respective overlapping portions EVDD_b toward the reference voltage line RL. For example, the first and second connection lines EVDD_1a and EVDD_2a may extend from the respective overlapping portions EVDD_b toward the third connection line EVDD_3a. The first and second connection lines EVDD_1a and EVDD_2a may be arranged generally in the horizontal direction X, excluding a portion that bends depending on the shape of a light-shielding pattern (LS in FIG. 5A).

The first and second connection lines EVDD_1a and EVDD_2a may be arranged not to overlap the respective branch lines of the data lines DL1, DL2, DL3, and DL4 and the reference voltage lines RL. To this end, the first and second connection lines EVDD_1a and EVDD_2a may be arranged at different sides of the circuit part with respect to the vertical direction Y.

For example, the first connection line EVDD_1a may be arranged at the upper side of the first and second circuit parts CA1 and CA2 of the first pixel PXL1, while the second connection line EVDD_2a may be arranged at the lower side of the third and fourth circuit parts CA3 and CA4 of the first prime pixel PXL1′ that is adjacent to the first pixel PXL1 with respect to the reference voltage line RL.

In another example, the first connection line EVDD_1a may be arranged at the upper side of the third prime and fourth prime circuit parts CA3′ and CA4′ of the second pixel PXL2, while the second connection line EVDD_2a may be arranged at the lower side of the first prime and second prime circuit parts CA1′ and CA2′ of the second prime pixel PXL2′ that is adjacent to the second pixel PXL2 with respect to the reference voltage line RL.

The third connection line EVDD_3a may be bent from each of the first and second connection lines EVDD_1a and EVDD_2a and may be arranged in the vertical direction Y. The third connection line EVDD_3a may have an overlapping region along the longitudinal direction of the reference voltage line RL. For example, the third connection line EVDD_3a may be overlapped with the reference voltage line RL along the longitudinal direction of the reference voltage line RL. Here, the longitudinal direction of the reference voltage line RL refers to the direction in which the reference voltage line RL is arranged in the display panel.

The reference voltage line RL may be arranged between each pair of the driving voltage lines VDDL. For example, the reference voltage line RL may be arranged between each pair of the second and third data lines DL2 and DL3.

The reference voltage line RL may supply a reference voltage to each of the sub-pixels arranged at opposite sides in the horizontal direction X. For example, the reference voltage line RL may be connected to the respective sub-pixels through branch lines that extend from the reference voltage line RL to the circuit parts of the respective sub-pixels at opposite sides.

FIG. 5A illustrates an enlarged view of any two circuit parts CA1 and CA2. Meanwhile, the first to fourth circuit parts CA1, CA2, CA3, and CA4 of the first pixel PXL1 and the first prime to fourth prime circuit parts CA1′, CA2′, CA3′, and CA4′ of the second pixel PXL2 in FIG. 3 may have the same structure as the circuit parts illustrated and described in FIG. 5A.

As shown in FIG. 5A, the first circuit part CA1 according to an embodiment is connected to the branch line DL1_1 of the first data line DL1, the branch line RL_1 of the reference voltage line RL, and the driving voltage connection pattern EVDD_1, and may include a first switch element T1, a second switch element T2, a driving element DT, and a capacitor.

The second circuit part CA2 according to an embodiment is connected to the branch line DL2_1 of the second data line DL2, the branch line RL_2 of the reference voltage line RL, and the driving voltage connection pattern EVDD_1, and may include a first switch element T1, a second switch element T2, a driving element DT, and a light-shielding layer LS. However, the structures of the circuit parts CA1, CA2, CA3, CA4, CA1′, CA2′, CA3′, and CA4′ are illustrative, and embodiments of the present specification are not limited thereto. Hereinafter, the first and second switch elements, the driving element, and the capacitor will be described based on the second circuit part CA2.

The light-shielding layer LS is formed as any one electrode of the capacitor and may have a light-blocking function to block light directed to active layers ACT1, ACT2, and ACT3.

The capacitor may include the light-shielding layer LS, the first active layer ACT1 of the first switch element T1, and an insulator between the light-shielding layer LS and the first active layer ACT1.

The first switch element T1 may be turned on in response to a gate pulse of the second gate line GL2.

The first switch element T1 may include the first active layer ACT1 and the first-first contact portion CT1_1 and first-second contact portion CT1_2 at opposite sides of the first active layer ACT1. The first switch element T1 may be connected to the second data line DL2 through the first-first contact portion CT1_1 and may be connected to the gate electrode GT of the driving element DT through the first-second contact portion CT1_2. Here, the first-first and first-second contact portions CT1_1 and CT1_2 may include respective electrodes for connection to the second data line DL2 and the gate electrode GT.

The second switch element T2 may be turned on in response to a gate pulse of the second gate line GL2.

The second switch element T2 may include the second active layer ACT2 and the second-first contact portion CT2_1 and second-second contact portion CT2_2 at opposite sides of the second active layer ACT2. The second switch element T2 may be connected to the reference voltage line RL through the second-first contact portion CT2_1 and may be connected to the light-shielding layer LS through the second-second contact portion CT2_2. Here, the second-first and second-second contact portions CT2_1 and CT2_2 may include respective electrodes for connection to the reference voltage line RL and the capacitor C.

The driving element DT may be turned on when a signal is applied to the gate electrode GT.

The driving element DT may include the third active layer ACT3 and the third-first contact portion CT3_1 and third-second contact portion CT3_2 at opposite sides of the third active layer ACT3. The gate electrode GL of the driving element DT may be connected to the first active layer ACT1 of the first switch element T1. The driving element DT may be connected to the driving voltage connection pattern EVDD_1 through the third-first contact portion CT3_1 and may be connected to the second active layer ACT2 of the second switch element T2 through the third-second contact portion CT3_2. Here, the third-first and third-second contact portions CT3_1 and CT3_2 may include respective electrodes for connection to the driving voltage connection pattern EVDD_1 and the second active layer ACT2 of the second switch element T2.

Also, the driving element DT may drive a light-emitting element by being connected to the anode electrode of the light-emitting element through the third-second contact portion CT3_2. Here, the third-second contact portion CT3_2 may include an electrode for connection to the anode electrode of the light-emitting element.

Meanwhile, the first gate line GL1 may be formed to have a plurality of layers GL1_1 and GL1_2 in some regions. Also, the first gate line GL1 may branch at the points at which it intersects the driving voltage line VDDL, the first and second data lines DL1 and DL2, and the reference voltage line RL. The second gate line GL2 may have the same structure as the first gate line GL1.

The first gate line GL1 may include a first layer GL1_1 and a second layer GL1_2. The first layer GL1_1 may be a gate line extending from the pad component. The second layer GL1_2 may be arranged in some regions in which there is no intersection with the signal lines (e.g., DL1_1, DL2_1, RL_1, and RL_2) on the layer different from the first layer GL1_1. However, the structures of the first and second gate lines GL1 and GL2 are illustrative, and embodiments of the present specification are not limited thereto.

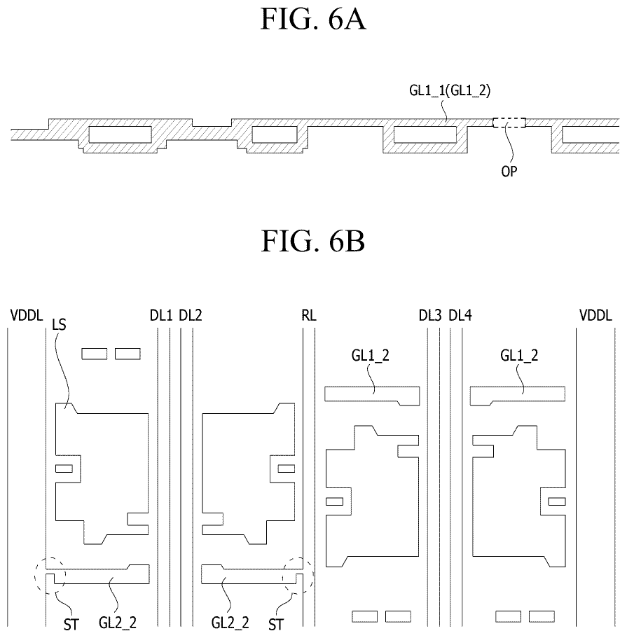

FIG. 6A is a view illustrating defective wire state 1 of a gate line according to an example embodiment. FIG. 6B is a view illustrating defective wire state 2 of a gate line according to an example embodiment.

As described above, the first gate line GL1 may include the first layer GL1_1 and the second layer GL1_2. The gate lines GL may be formed through a thin-film deposition and etching process. During this process, the gate line GL may become defective if an area that should not be etched is etched (state 1) or if an area that should be etched is not etched (state 2).

FIG. 6A illustrates state 1 in which a defect occurs whereby a portion of the first gate line GL1 is open. For example, the portion of the first gate line GL1 is the area that should not be etched. The display panel according to an example embodiment of the present specification may include an open portion OP in any one first gate line GL1 as it has state 1. For example, state 1 may occur in a single wire area in which a wire is not configured as a double-layer or a wire does not branch. Accordingly, the first gate line GL1 in state 1 may include the open portion OP in the first layer GL1_1. In particular, the open portion OP may be located in a region of the first layer GL1_1 that does not overlap the second layer GL1_2.

However, state 1 described above is illustrative, and embodiments of the present specification are not limited thereto. For example, state 1 may occur in the second gate line GL2, and the open portion OP may occur at any location in the gate line. In particular, the open portion OP may be located in a region of the second layer GL1_2 that does not overlap the first layer GL1_1.

FIG. 6B illustrates state 2 in which a defect occurs whereby a portion of the second gate line GL2 is shorted to another signal line adjacent thereto. The display panel according to an example embodiment of the present specification, while in state 2, may include a short-circuit portion ST in any one second gate line GL2. For example, the second gate line GL2 in state 2 may include the short-circuit portion ST in the second layer GL2_2. For example, the short-circuit portion ST may be connected to the driving voltage line VDDL that is arranged adjacent to the second layer GL2_2 of the second gate line GL2. For example, the short-circuit portion ST may be connected to the reference voltage line RL that is arranged adjacent to the second layer GL2_2 of the second gate line GL2. However, state 2 described above is illustrative, and embodiments of the present specification are not limited thereto.

Accordingly, the display panel according to an example embodiment of the present specification may perform repair for state 1 and state 2 as follows.

Here, when state 2 is repaired, a process for cutting the short-circuit portion ST may be added. As the short-circuit portion ST is cut, an open portion OP may be formed in the second gate line GL2. Accordingly, in the following repair process, repairing the open portion OP of the second gate line GL2 will be described.

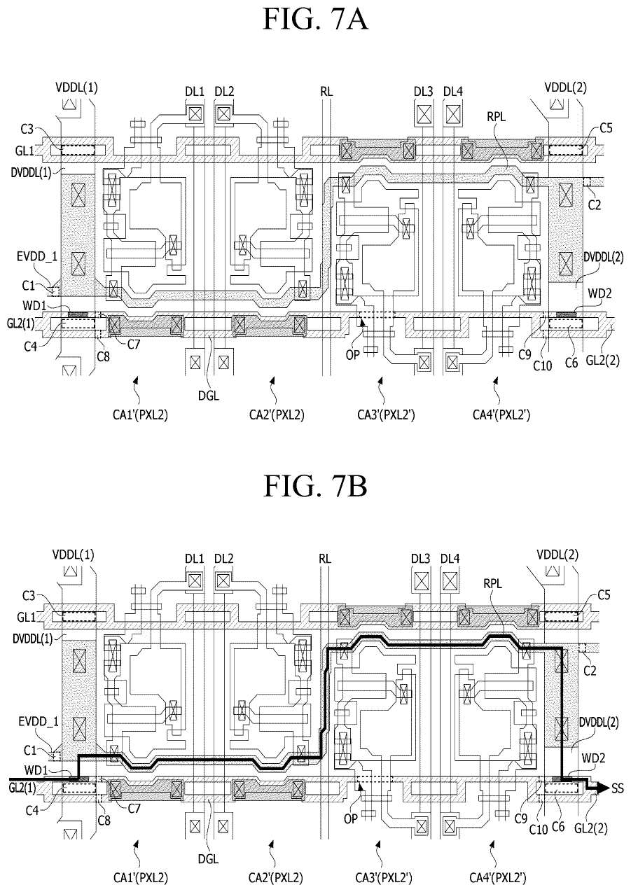

FIG. 7A a plan view of a display panel according to an example embodiment of the present specification. FIG. 7B is a plan view illustrating a signal path of a repaired gate line according to an example embodiment.

As shown in FIG. 7A, the display panel according to an example embodiment may include a first driving voltage line VDDL(1) and a second driving voltage line VDDL(2) spaced apart from each other with pixels PXL (PXL1, PXL1′, PXL2, and PXL2′) therebetween, a plurality of driving voltage connection patterns EVDD_1 configured to connect the first and second driving voltage lines VDDL(1) and VDDL(2), and a plurality of gate lines GL (GL1 and GL2) that intersect the first and second driving voltage lines VDDL(1) and VDDL(2). Here, the plurality of gate lines GL may include at least one gate line GL including an open portion OP, and the plurality of driving voltage connection patterns EVDD_1 may include a repair pattern RPL that is separated from the first and second driving voltage lines VDDL(1) and VDDL(2) to connect the two ends of the at least one gate line disconnected by the open portion OP.

The display panel according to an embodiment of the present specification is assumed to include the open portion OP in the second gate line GL2, among the plurality of gate lines GL1 and GL2. For example, the open portion OP may overlap the branch line DL3_3 of the third data line DL3 and the branch line RL_3 of the reference voltage line RL. Alternatively, the open portion OP may be included in the first gate line GL1, among the plurality of gate lines GL1 and GL2.

The repair method according to an example embodiment may be performed for each driving voltage connection pattern EVDD_1. The display panel according to an example embodiment of the present specification may repair the defective second gate line GL2 in such a way that the repair pattern RPL separated from the first and second driving voltage lines VDDL(1) and VDDL(2) connects the open portion OP of the second gate line GL2. As a result, the repaired second gate line GL2 allows a gate pulse to flow normally through the repair pattern RPL.

To this end, the display panel according to an example embodiment of the present specification may form a driving voltage line MVDDL, including a plurality of driving voltage lines VDDL and a plurality of driving voltage connection patterns EVDD_1, in the form of a mesh. The driving voltage line MVDDL in the form of a mesh may supply a driving voltage to the entire display area even though the repair pattern RPL is used in some regions.

The plurality of driving voltage lines VDDL may include the first driving voltage line VDDL(1) and the second driving voltage line VDDL(2) that are arranged adjacent to each other with a pixel PXL therebetween.

The first and second driving voltage lines VDDL(1) and VDDL(2) may include a first dummy driving voltage line DVDDL(1) and a second dummy driving voltage line DVDDL(2), respectively, which are separated by cutting portions C3, C4, C5, and C6. That is, by forming cutting portions C3, C4, C5, and C6 in the first and second driving voltage lines VDDL(1) and VDDL(2), the first dummy driving voltage line DVDDL(1) and the second dummy driving voltage line DVDDL(2) can be manufactured. The first dummy driving voltage line DVDDL(1) can be an area between the third cutting portion C3 and the fourth cutting portion C4. The second dummy driving voltage line DVDDL(2) can be an area between the fifth cutting portion C5 and the sixth cutting portion C6. The first and second dummy driving voltage lines DVDDL(1) and DVDDL(2) that are not supplied with a driving voltage may be used to electrically connect the repair pattern RPL and repair gate lines GL2(1) and GL2(2).

The first and second driving voltage lines VDDL(1) and VDDL(2) may include the third cutting portion C3, the fourth cutting portion C4, the fifth cutting portion C5, and the sixth cutting portion C6. Accordingly, the driving voltage may be blocked in the circuit parts in the region in which repair is performed.

The third and fourth cutting portions C3 and C4 may be formed in the first driving voltage line VDDL(1). For example, the first driving voltage line VDDL(1) may include the first dummy driving voltage line DVDDL(1) between the third cutting portion C3 and the fourth cutting portion C4. The fifth and sixth cutting portions C5 and C6 may be formed in the second driving voltage line VDDL(2). For example, the second driving voltage line VDDL(2) may include the second dummy driving voltage line DVDDL(2) between the fifth cutting portion C5 and the sixth cutting portion C6. The fifth and sixth cutting portions C5 and C6 may be formed in the second driving voltage line VDDL(2). The third to sixth cutting portions C3, C4, C5, and C6 may be located between the branch lines of the first and second gate lines GL1 and GL2. Accordingly, the display panel according to an embodiment of the present specification uses the branch lines of the gate lines as reference points during the cutting process, thereby facilitating cutting.

The first dummy driving voltage line DVDDL(1) may contact the overlapping portion located at one side of the repair pattern RPL through a fifth contact portion and may contact the first repair gate line GL2(1) through a first connection portion WD1. The second dummy driving voltage line DVDDL(2) may contact the overlapping portion located at the other side of the repair pattern RPL through a fifth contact portion and may contact the second repair gate line GL2(2) through a second connection portion WD2.

The plurality of driving voltage connection patterns EVDDL_1 may include the repair pattern RPL that connects the open portion OP of the defective second gate line GL2. The repair pattern RPL may be disconnected from the two connection lines EVDD_a adjacent thereto in the horizontal direction X by a first cutting portion C1 and a second cutting portion C2. In other words, the repair pattern RPL may be determined by the first and second cutting portions CT1 and CT2. The repair pattern RPL may include two overlapping portions EVDD_b adjacent to each other and a connection line EVDD_a therebetween.

The plurality of gate lines GL1 and GL2 may include at least one second gate line GL2 including the open portion OP. The second gate line GL2 including the open portion OP may include a dummy gate line DGL, which is arranged between cutting portions C7, C8, C9, and C10 and includes the open portion OP, the first repair gate line GL2(1) connected to the repair pattern RPL through the first connection portion WD1, and the second repair gate line GL2(2) connected to the repair pattern RPL through the second connection portion WD2.

The dummy gate line DGL is separated from the first and second repair gate lines GL2(1) and GL2(2) and may include the open portion OP. The dummy gate line DGL may be determined by the seventh to tenth cutting portions C7, C8, C9, and C10.

The first and second repair gate lines GL2(1) and GL2(2) may have the first connection portion WD1 and the second connection portion WD2, respectively, in the regions that respectively overlap the two adjacent dummy driving voltage lines DVDDL(1) and DVDDL(2). The second gate line GL2 may be electrically connected to the repair pattern RPL through the first and second connection portions WD1 and WD2.

In the first connection portion WD1, the first repair gate line GL2(1) and the first dummy driving voltage line DVDDL(1) arranged on different layers may contact each other. In the second connection portion WD2, the second repair gate line GL2(2) and the second dummy driving voltage line DVDDL(2) arranged on different layers may contact each other. Each of the repair gate lines GL2(1) and GL2(2) and a corresponding one of the dummy driving voltage lines DVDDL(1) and DVDDL(2) may be contacted by welding one of them through a laser process. However, the method of contacting each of the repair gate lines GL2(1) and GL2(2) and a corresponding one of the dummy driving voltage lines DVDDL(1) and DVDDL(2) is illustrative, and the display panel according to an embodiment of the present specification is not limited thereto.

For example, the first connection portion WD1 may be located at an intersection of the first repair gate line GL2(1) and the first dummy driving voltage line DVDDL(1), and the second connection portion WD2 may be located at an intersection of the second repair gate line GL2(2) and the second dummy driving voltage line DVDDL(2), but is not limited thereto.

The circuit parts in the region in which repair is performed may not operate normally because a driving voltage is not supplied thereto. Here, the circuit parts in the region in which repair is performed may include cutting portions in the driving voltage lines VDDL and the second gate line GL2 to prevent or suppress malfunctioning.

The second gate line 2 may further include the seventh cutting portion C7, the eighth cutting portion C8, the ninth cutting portion C9, and the tenth cutting portion C10. Accordingly, a gate pulse may be blocked in the circuit parts in the region in which repair is performed.

The seventh to tenth cutting portions C7, C8, C9, and C10 may be located farther outward than the signal lines of the circuit parts to which signals of the second gate line GL2 are supplied, at least in the region in which repair is performed. For example, the seventh to tenth cutting portions C7, C8, C9, and C10 may be located farther outward than the third and fourth circuit parts CA3′ and CA4′ to which signals of the second gate line GL2 are supplied. For example, with respect to different driving voltage lines VDDL between which the repair pattern is arranged, the seventh to tenth cutting portions C7, C8, C9, and C10 may be respectively formed in the region of the second gate line GL2 adjacent to one of the driving voltage lines VDDL and in the region of the second gate line GL2 adjacent to the other one of the driving voltage lines VDDL.

However, the number and locations of cutting portions in the display panel according to an embodiment of the present specification are not limited to those illustrated and described. For example, the seventh and eighth cutting portions C7 and C8 or the ninth and tenth cutting portions C9 and C10 formed in the second gate line GL2 may be formed as a single cutting portion.

Also, to prevent or suppress malfunction of the circuit part caused by supply of various signals to the region in which repair is performed, cutting portions for disconnecting the branch lines DL1_1, DL2_1, DL3_1, and DL4_1 of the first to fourth data lines DL1, DL2, DL3, and DL4 and the branch lines RL_1, RL_2, RL_3, and RL_4 of the reference voltage line RL that are connected to the circuit parts CA1, CA2, CA3, and CA4 may be further included.

As shown in FIG. 7B, the repaired second gate line GL2 may supply a gate pulse along the first signal path SS. The first signal path SS may sequentially proceed along the first repair gate line GL2(1), the first dummy driving voltage line DVDDL(1), the repair pattern RPL, the second dummy driving voltage line DVDDL(2), and the second repair gate line GL2(2).

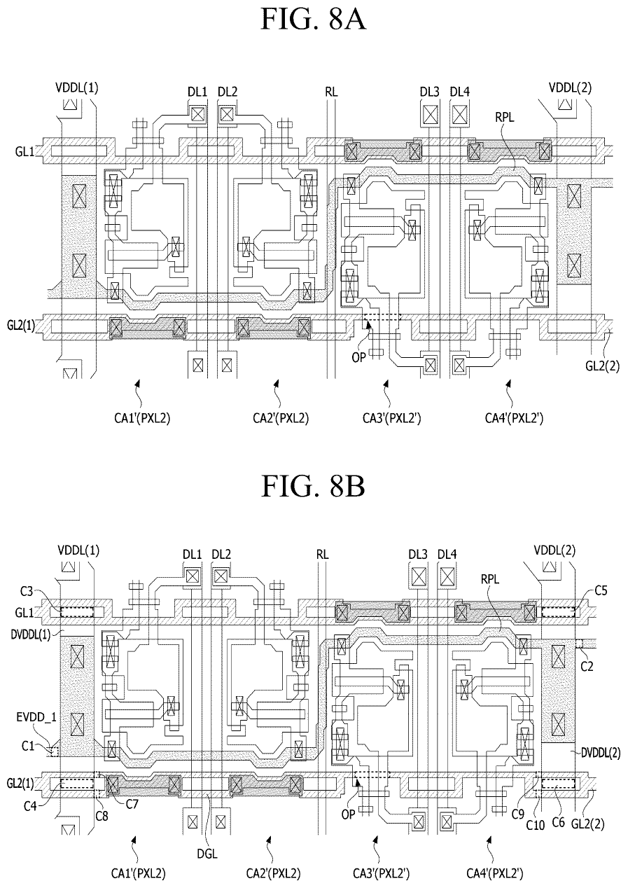

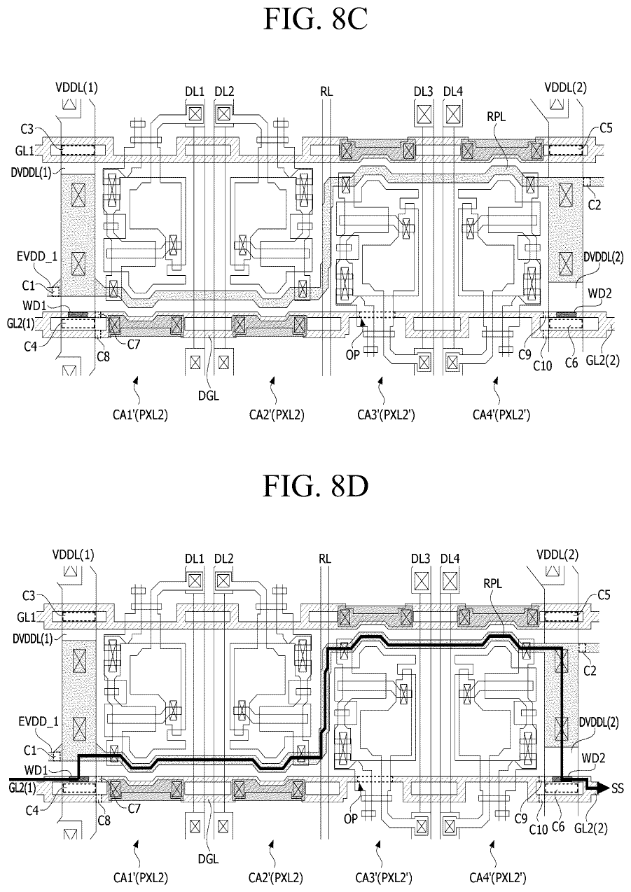

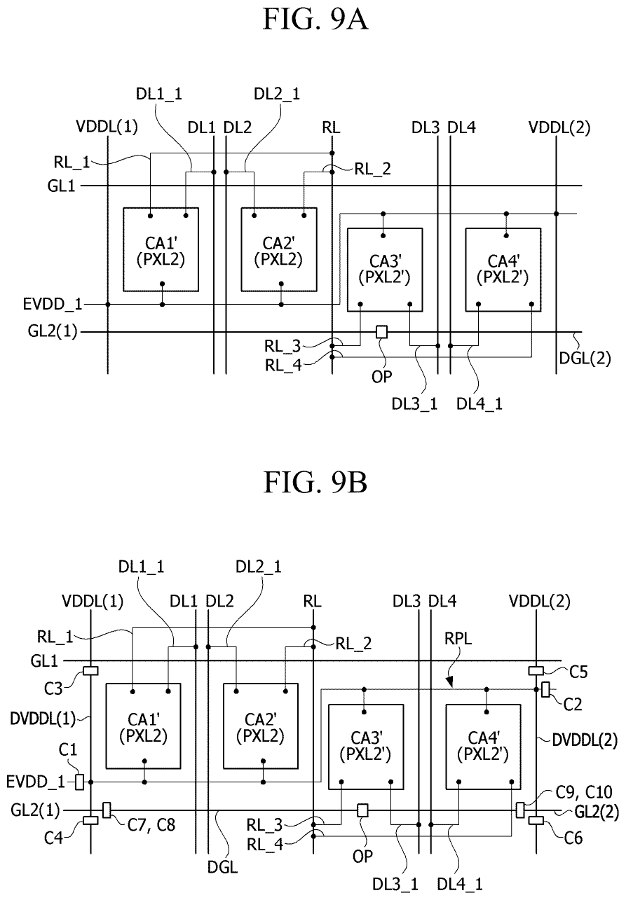

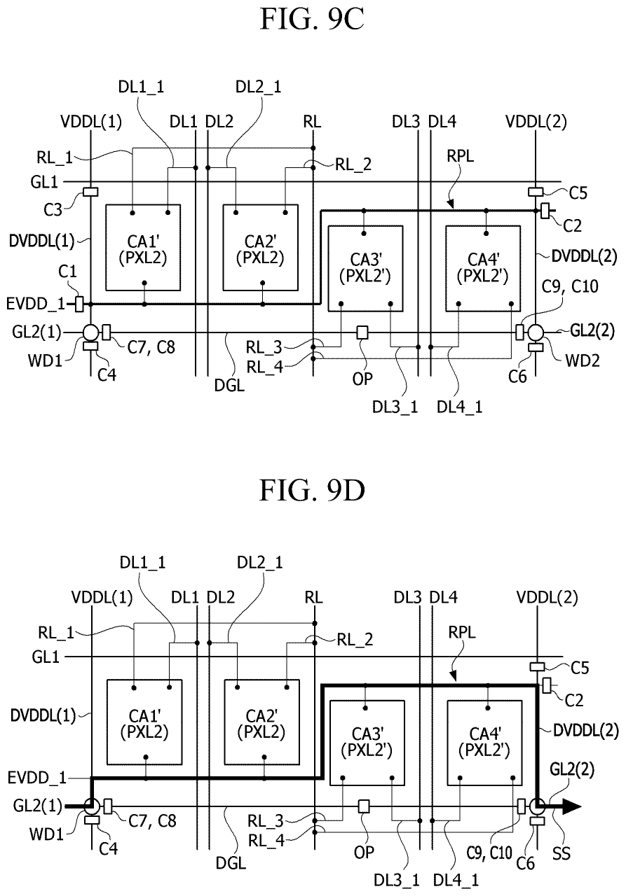

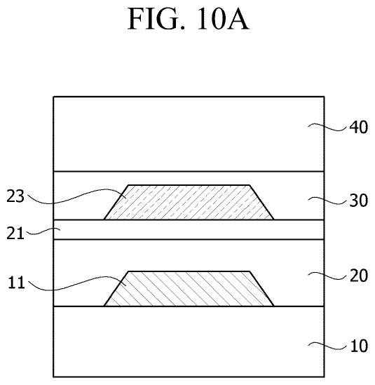

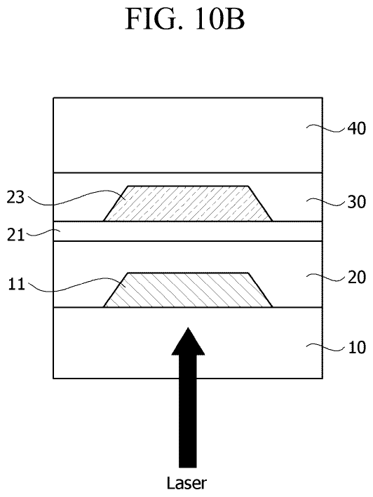

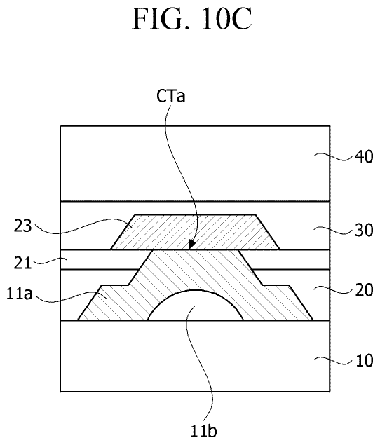

FIGS. 8A to 8D are plan views illustrating a repair process according to an example embodiment. FIGS. 9A to 9D are circuit schematics illustrating a repair process according to an example embodiment. FIGS. 10A to 10C are cross-sectional views illustrating a repair process according to an example embodiment.

FIGS. 9A to 9D are circuit schematics that correspond to FIGS. 8A to 8D, respectively. Also, FIGS. 8A, 8B, 8C, and 8D illustrate the same process steps as those illustrated in FIGS. 9A, 9B, 9C, and 9D, respectively. FIGS. 10A to 10C are cross-sectional views illustrating the process for the connection portions WD1 and WD2 formed in the process illustrated in FIGS. 8C and 9C.

Also, the welding process in FIGS. 8C and 9C may be performed before the cutting process in FIGS. 8B and 9B.

As shown in FIGS. 8A and 9A, an open portion OP may be included in the second gate line GL2. The open portion OP may be arranged in the second gate line GL2 adjacent to the third prime circuit part CA3′. For example, the open portion OP may overlap at least one of the branch line DL3_1 of the third data line DL3 and the branch line RL_3 of the reference voltage line RL.

As shown in FIGS. 8B and 9B, first to tenth cutting portions C1, C2, C3, C4, C5, C6, C7, C8, C9, and C10 may be formed through the cutting process. The first to tenth cutting portions C1, C2, C3, C4, C5, C6, C7, C8, C9, and C10 may be located outside the region in which repair is performed. The first to tenth cutting portions C1, C2, C3, C4, C5, C6, C7, C8, C9, and C10 may cut portion of the corresponding signal lines through a laser process. Accordingly, the first to tenth cutting portions C1, C2, C3, C4, C5, C6, C7, C8, C9, and C10 may prevent or suppress malfunction of the circuit part that is caused by supply of various signals to the region in which repair is performed. For example, the first driving voltage line VDDL(1) may include the first dummy driving voltage line DVDDL(1) formed between the third and fourth cutting portions C3 and C4, and the second driving voltage line VDDL(2) may include the second dummy driving voltage line DVDDL(2) formed between the fifth and sixth cutting portions C5 and C6.

The first and second cutting portions C1 and C2 may be formed in the driving voltage connection pattern EVDD_1. Here, the driving voltage connection pattern EVDD_1 between the first and second cutting portions C1 and C2 may become a repair pattern RPL.

The third to sixth cutting portions C3, C4, C5, and C6 may be formed in the driving voltage lines VDDL. A first dummy driving voltage line DVDDL(1) may be formed between the third and fourth cutting portions C3 and C4, and a second dummy driving voltage line DVDDL(2) may be formed between the fifth and sixth cutting portions C5 and C6. As a result, a driving voltage may be blocked in the region in which repair is performed.

The seventh to tenth cutting portions C7, C8, C9, and C10 may be formed in the second gate line GL2. A dummy gate line DGL including the open portion OP may be formed between the seventh and eighth cutting portions C7 and C8 and the ninth and tenth cutting portions C9, C10. For example, the second gate line GL2 including the open portion OP may include the dummy gate line DGL formed between the seventh and eighth cutting portions C7 and C8 and the ninth and tenth cutting portions C9, C10. A first repair gate line GL2(1) overlapping the first dummy driving voltage line DVDDL(1) and a second repair gate line GL(2) overlapping the second dummy driving voltage line DVDDL(2) may be formed. As a result, a gate pulse may be blocked in the region in which repair is performed.

However, the number and locations of cutting portions in the display panel according to an embodiment of the present specification are not limited to those illustrated and described.

As shown in FIGS. 8C and 9C, connection portions WD1 and WD2 may be formed in regions in which the repair gate lines GL2(1) and GL2(2) overlap the dummy driving voltage lines DVDDL(1) and DVDDL(2) through a welding process. The first connection portion WD1 may be formed in the region in which the first repair gate line GL2(1) overlaps the first dummy driving voltage line DVDDL(1), and the second connection portion WD2 may be formed in the region in which the second repair gate line GL2(2) overlaps the second dummy driving voltage line DVDDL(2). The first and second connection portions WD1 and WD2 may electrically connect the repair gate lines GL2(1) and GL2(2) and the repair pattern RPL via the dummy driving voltage lines DVDDL(1) and DVDDL(2).

In each of the first and second connection portions WD1 and WD2, each of the repair gate lines GL2(1) and GL2(2) and a corresponding one of the dummy driving voltage lines DVDDL(1) and DVDDL(2), which are arranged on different layers, may be contacted by welding one of them. However, the method of contacting each of the repair gate lines GL2(1) and GL2(2) and a corresponding one of the dummy driving voltage lines DVDDL(1) and DVDDL(2) is illustrative, and the display panel according to an example embodiment of the present disclosure is not limited thereto. The method of forming the first and second connection portions WD1 and WD2 will be described with reference to FIGS. 10A to 10C.

As shown in FIG. 10A, the display panel according to an example embodiment of the present specification may include a substrate 10, a driving voltage line 11 arranged on the substrate 10, a first insulating layer 20 configured to cover the driving voltage line 11, a second insulating layer 21 arranged on the first insulating layer 20, a second gate line 23 arranged on the second insulating layer 21, a third insulating layer 30 configured to cover the second gate line 23, and a fourth insulating layer 40 arranged on the third insulating layer 30.

For example, the driving voltage line 11 may be arranged on a portion of the substrate 10, and the second gate line 23 may be arranged on a portion of the second insulating layer 21. The first insulating layer 20 may be configured to cover the driving voltage line 11 and the portion of the substrate 10 exposed by the driving voltage line 11, and the third insulating layer 30 may be configured to cover the second gate line 23 and the portion of the second insulating layer 21 exposed by the second gate line 23, but is not limited thereto.

As shown in FIG. 10B, a laser process may be performed by emitting laser from below the substrate 10. Through the laser process, the driving voltage line 11 may be welded.

As shown in FIG. 10C, the welded driving voltage line 11a may contact the second gate line 23. Here, the laser process may be terminated when the welded driving voltage line 11a and the second gate line 23 are contacted (CTa). Here, a void 11b may be formed between the welded driving voltage line 11a and the substrate 10.

As shown in FIGS. 8D and 9D, the first and second connection portions WD1 and WD2 are formed, whereby a gate pulse of the second gate line GL2 may be supplied through the repair pattern RPL. Accordingly, the first signal path SS along which the gate pulse of the second gate line GL2 is supplied may sequentially proceed along the first repair gate line GL2(1), the first dummy driving voltage line DVDDL(1), the repair pattern RPL, the second dummy driving voltage line DVDDL(2), and the second repair gate line GL2(2).

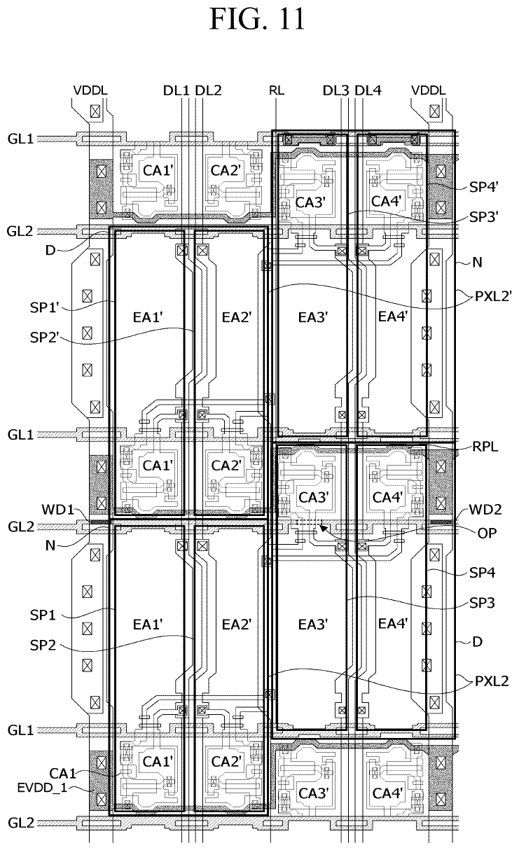

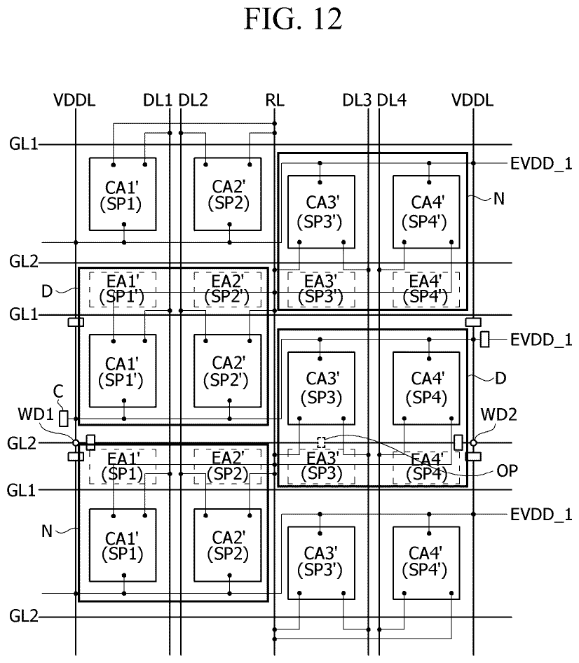

FIG. 11 is a plan view illustrating a defective pixel according to an example embodiment. FIG. 12 is a circuit schematic illustrating a defective pixel according to an example embodiment. FIGS. 11 and 12 show the state in which the above-described repair process is performed.

As shown in FIGS. 11 and 12, the display panel according to an example embodiment of the present specification includes an open portion OP in any one second gate line GL2, among a plurality of first and second gate lines GL1 and GL2, and may include a repair pattern RPL configured to repair the open portion OP.

When the repair process for the second gate line GL2 is performed, the third prime and fourth prime circuit parts CA3′ and CA4′ of the second pixel PXL2 and the first prime and second prime circuit parts CA1′ and CA2′ of the second prime pixel PXL2′ may not be supplied with normal signals. For example, the third and fourth sub-pixels SP3 and SP4 of the second pixel PXL2 and the first prime and second prime sub-pixels SP1′ and SP2′ of the second prime pixel PXL2′ may be in a non-operating state D.

On the other hand, the first prime and second prime circuit parts CA1′ and CA2′ of the second pixel PXL2 and the third prime and fourth prime circuit parts CA3′ and CA4′ of the second prime pixel PXL2′ may be supplied with normal signals. For example, the first and second sub-pixels SP1 and SP2 of the second pixel PXL2 and the third prime and fourth prime sub-pixels SP3′ and SP4′ of the second prime pixel PXL2′ may be in a normal state N.

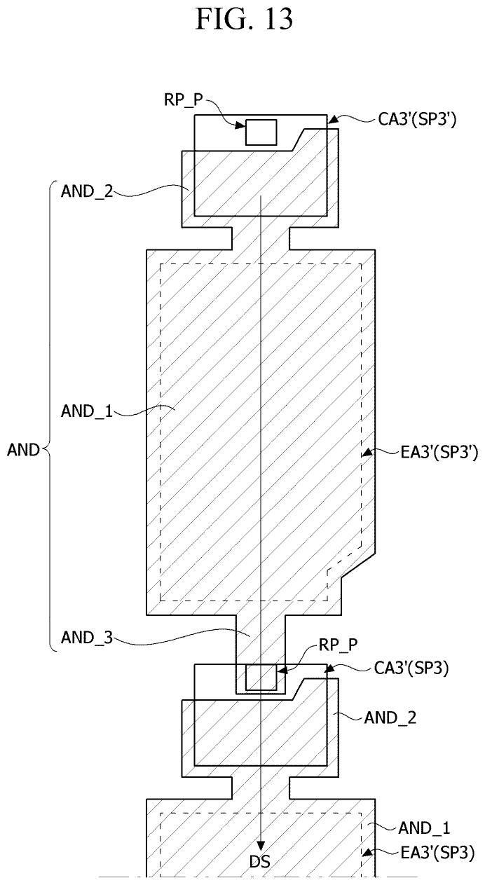

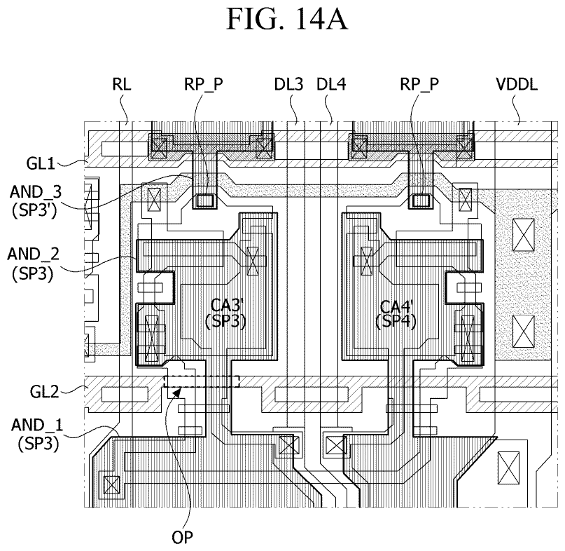

FIG. 13 is a view schematically illustrating a data copy repair method of a defective pixel according to an example embodiment.

As shown in FIG. 13, the display panel according to an example embodiment of the present specification may include an anode electrode AND corresponding to each sub-pixel and a pixel repair component RP_P arranged in the circuit part of each sub-pixel.

The anode electrode AND according to an example embodiment of the present specification may be arranged to correspond to each of a plurality of sub-pixels SP1, SP2, SP3, SP4, SP1′, SP2′, SP3′, and SP4′. For example, the anode electrode AND corresponding to a third prime sub-pixel SP3′ may include a first anode electrode portion AND_1 overlapping a third 3′-th emitting component EA3′, a second anode electrode portion AND_2 overlapping a third prime circuit part CA3′, and a third anode electrode portion AND_3 extending from the first anode electrode portion AND_1 to a third sub-pixel SP3. Here, the third anode electrode portion AND_3 of the third prime sub-pixel SP3′ may partially overlap the pixel repair component RP_P arranged in the third prime circuit part CA3′ of the third sub-pixel SP3.

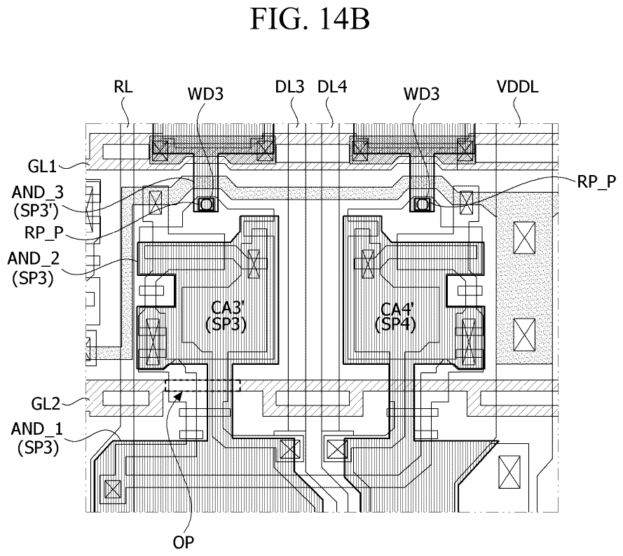

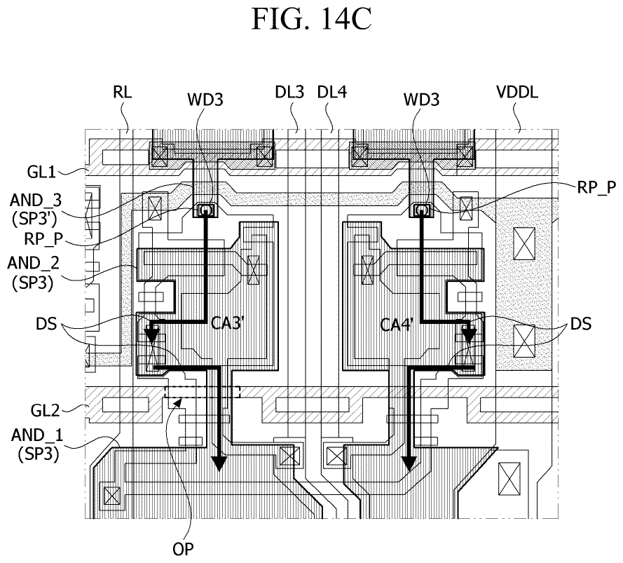

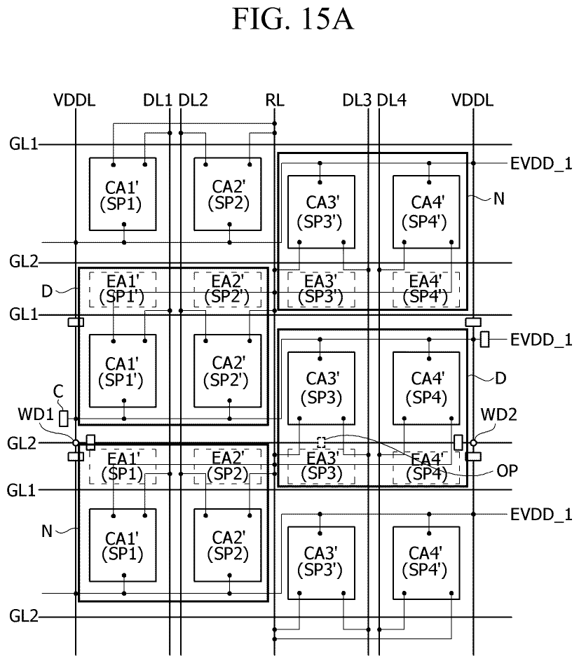

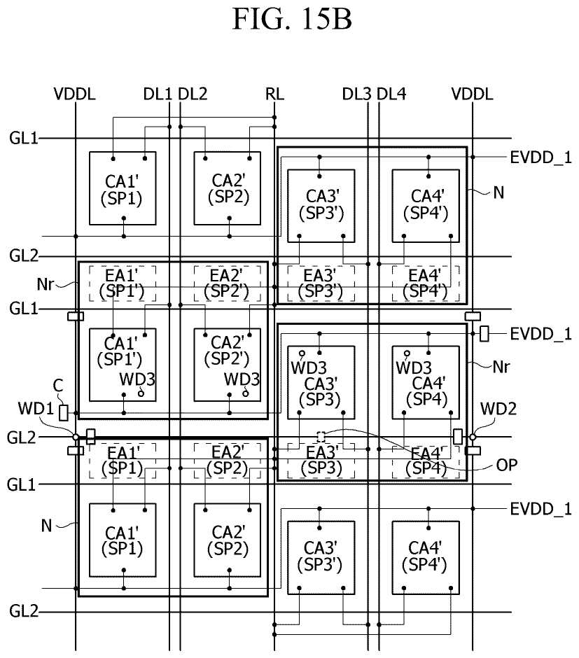

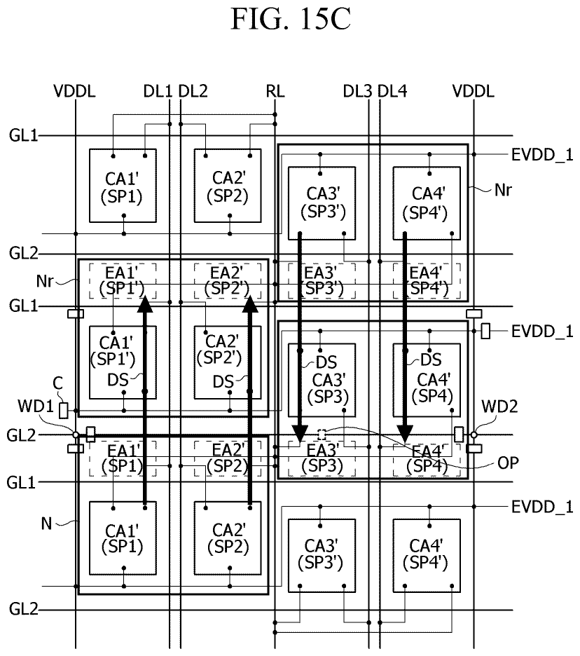

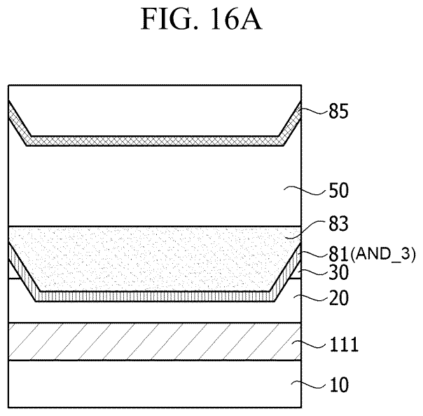

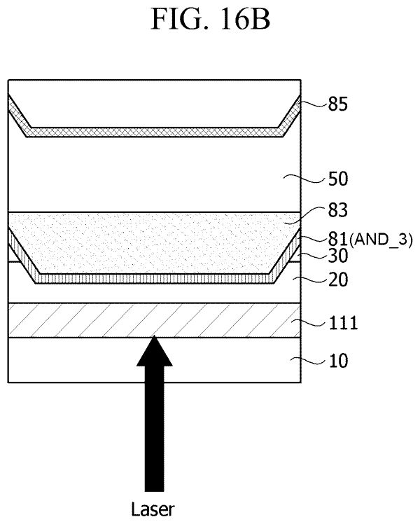

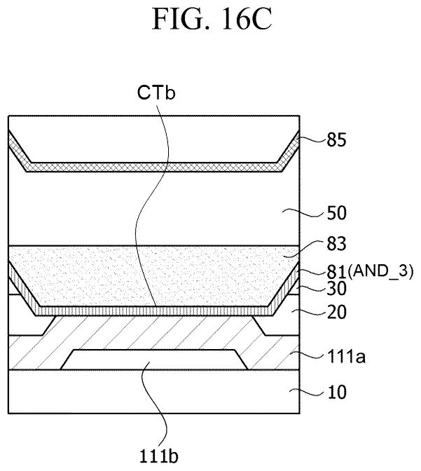

FIGS. 14A to 14C are plan views illustrating a pixel repair process according to an example embodiment. FIGS. 15A to 15C are circuit schematics illustrating a pixel repair process according to an example embodiment. FIGS. 16A to 16C are cross-sectional views illustrating a pixel repair process according to an example embodiment. FIGS. 14A to 14C illustrate the same process steps as those in FIGS. 15A to 15C, respectively.

As shown in FIGS. 14A and 15A, the third anode electrode portion AND_3 corresponding to a third prime sub-pixel SP3′ may overlap the light-shielding layer LS arranged in the third prime circuit part CA3′ of a third sub-pixel SP3. Here, the light-shielding layer LS includes a pixel repair component RP_P, so the pixel repair component RP_P may overlap the third anode electrode portion AND_3.

As shown in FIGS. 14B and 15B, a third connection portion WD3 may be formed in the pixel repair component RP_P. In the third connection portion WD3, the third anode electrode portion AND_3 of the third prime sub-pixel SP3′ and the light-shielding layer LS of the third sub-pixel SP3 may contact each other. For example, the third anode electrode portion AND_3 of the third prime sub-pixel SP3′ or the light-shielding layer LS of the third sub-pixel SP3 is welded through a laser process, whereby the third anode electrode portion AND_3 and the light-shielding layer LS may be contacted. The method of forming the third connection portion WD3 will be described with reference to FIGS. 16A to 16C.

As shown in FIG. 16A, the display panel according to an example embodiment of the present specification may include a substrate 10, a light-shielding layer 111 arranged on the substrate 10, a first insulating layer 20 configured to cover the light-shielding layer 111, a third insulating layer 30 arranged on the first insulating layer 20, a fifth insulating layer 50 arranged on the third insulating layer 30, a third anode electrode portion 81 arranged between the first insulating layer 20 and the fifth insulating layer 50, an intermediate layer 83 arranged on the third anode electrode portion 81, and a cathode electrode 85 arranged on the fifth insulating layer 50. For example, the third anode electrode portion 81 may be arranged the first insulating layer 20 and the third insulating layer 30, and the fifth insulating layer 50 may be arranged on the intermediate layer 83.

Here, the third anode electrode portion 81 is identical to the third anode electrode portion AND_3 of the third prime sub-pixel SP3′ illustrated in FIGS. 14B and 15B, and the light-shielding layer 111 is identical to the light-shielding layer LS of the third sub-pixel SP3 illustrated in FIGS. 14B and 15B.

As shown in FIG. 16B, a laser process may be performed as laser is emitted from below the substrate 10. Through the laser process, the light-shielding layer 111 may be welded.

Referring to FIG. 16C, the welded light-shielding layer 111a may contact the third anode electrode portion AND_3. For example, an upper surface of the welded light-shielding layer 111a may contact a lower surface of the third anode electrode portion AND_3. Here, the laser process may be terminated as the welded light-shield layer 111a and the third anode electrode portion AND_3 are contacted (CTb). Here, a void 111b may be formed between the welded light-shielding layer 111a and the substrate 10.

As shown in FIGS. 14C and 15C, the pixel driving data of the third prime sub-pixel SP3′ may be transferred to the light-shielding layer LS of the third sub-pixel SP3 through the third connection portion WD3. Here, the light-shielding layer LS of the third sub-pixel SP3 may be electrically connected to the driving element that drives the third prime emitting component EA3′ of the third sub-pixel SP3 to emit light, and the driving element may be electrically connected to the second anode electrode portion AND_2 of the third sub-pixel SP3.

Accordingly, the driving data of the third prime sub-pixel SP3′ that is copied to the light-shielding layer LS of the third sub-pixel SP3 may be sequentially supplied to the second anode electrode portion AND_2 of the third sub-pixel SP3 and the first anode electrode portion AND_1 of the third sub-pixel SP3. For example, the second signal path DS of the pixel driving data that is supplied in the repaired normal state Nr may sequentially proceed along the third anode electrode portion AND_3 of the third prime sub-pixel SP3′, the light-shielding layer LS of the third sub-pixel SP3, the driving element of the third sub-pixel SP3, the second anode electrode portion AND_2 of the third sub-pixel SP3, and the first anode electrode portion AND_1 of the third sub-pixel SP3.

The above-described pixel repair process may be performed on the first prime, second prime, third prime, and fourth prime sub-pixels SP1′, SP2′, SP3, and SP4 in the non-operating state D. For example, the pixel repair process on the first prime sub-pixel SP1′ may be performed with the first sub-pixel SP1, the pixel repair process on the second prime sub-pixel SP2′ may be performed with the second sub-pixel SP2, the pixel repair process on the third sub-pixel SP3 may be performed with the third prime sub-pixel SP3′, and the pixel repair process on the fourth sub-pixel SP4 may be performed with the fourth prime sub-pixel SP4′.

Accordingly, the display panel according to one or more example embodiments of the present specification may normalize a defective pixel by copying data from adjacent pixels through the gate repair process.

Although the example embodiments of the present disclosure have been described in more detail with reference to the accompanying drawings, the present disclosure is not necessarily limited to these example embodiments, and various modifications may be made without departing from the technical spirit of the present disclosure.

Accordingly, the example embodiments disclosed in the present disclosure are not intended to limit the technical idea of the present disclosure, but are for illustrative purposes, and the scope of the technical idea of the present disclosure is not limited by these example embodiments.

Therefore, it should be understood that the example embodiments described above are illustrative in all respects and not limiting.

In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

### LIST OF REFERENCE NUMBERS

VDDL: driving voltage line
EVDD_1: driving voltage connection pattern
GL1: first gate line
GL2: second gate line
RPL: repair pattern
OP: open portion
DVDDL(1): first dummy driving voltage line
DVDDL(2): second dummy driving voltage line

What is claimed is:

1. A display panel, comprising:
a first driving voltage line and a second driving voltage line spaced apart from each other with a pixel therebetween;
a plurality of driving voltage connection patterns configured to connect the first and second driving voltage lines; and
a plurality of gate lines that intersect the first and second driving voltage lines,
wherein the plurality of gate lines include at least one gate line including an open portion, and p1 wherein the plurality of driving voltage connection patterns include a repair pattern configured to connect two ends of the at least one gate line disconnected by the open portion.

2. The display panel of claim 1, wherein each of the plurality of driving voltage connection patterns includes:
overlapping portions that contact the first and second driving voltage lines, respectively; and p1 a connection line configured to connect the overlapping portions, and
wherein the repair pattern includes the overlapping portions and the connection line.

3. The display panel of claim 2, wherein the first driving voltage line includes:
first cutting portions; and
a first dummy driving voltage line separated from the first driving voltage line with the first cutting portions interposed therebetween,
wherein the second driving voltage line includes:
second cutting portions; and
a second dummy driving voltage line electrically separated from the second driving voltage line with the second cutting portions interposed therebetween, and
wherein the overlapping portions of the repair pattern contact the first and second dummy driving voltage lines, respectively.

4. The display panel of claim 3, wherein:
the at least one gate line includes a first repair gate line and a second repair gate line spaced apart from each other with the open portion therebetween, and
the first and second repair gate lines are electrically connected to the overlapping portions of the repair pattern, respectively.

5. The display panel of claim 4, wherein:
the at least one gate line further includes a dummy gate line separated from the first and second repair gate line and including the open portion.

6. The display panel of claim 4, further comprising:
a first connection portion located at an intersection of the first repair gate line and the first dummy driving voltage line; and
a second connection portion located at an intersection of the second repair gate line and the second dummy driving voltage line,
wherein the first and second repair gate lines contact the first and second dummy driving voltage lines at the first and second connection portions, respectively.

7. The display panel of claim 2, further comprising:
a reference voltage line arranged between the first and second driving voltage lines,
wherein the connection line partially overlaps the reference voltage line along a longitudinal direction of the reference voltage line.

8. The display panel of claim 7, wherein:
the connection line comprises first and second connection lines extending from the respective overlapping portions toward the reference voltage line, and a third connection line arranged between the first and second connection lines.

9. The display panel of claim 8, wherein:
the first and second connection lines are arranged not to overlap the reference voltage lines, and
the third connection line partially overlaps the reference voltage line along a longitudinal direction of the reference voltage line.

10. The display panel of claim 1, wherein:
the pixel comprises a plurality of pixels including a first pixel and a second pixel,
each of the plurality of pixels includes a circuit part, an emitting component, and at least one anode electrode,
wherein the anode electrode includes:
a first anode electrode portion that overlaps the emitting component, a second anode electrode portion that overlaps the circuit part by extending from the first anode electrode portion; and
a third anode electrode portion that overlaps a circuit part of an adjacent another pixel by extending from the first anode electrode portion, and
wherein the third anode electrode portion of the first pixel contacts the circuit part of the second pixel through a third connection portion.

11. The display panel of claim 10, wherein:
the third connection portion is formed in a pixel repair component, and
the pixel repair component overlaps the third anode electrode portion.

12. The display panel of claim 1, wherein:
the pixel comprises a plurality of pixels including a first pixel and a second pixel,
each of the plurality of pixels includes a plurality of sub-pixels configured to emit a light of different colors, and
sub-pixels configured to emit a light of identical color in the first and second pixels are supplied with an identical data signal and different gate pulses.

13. The display panel of claim 12, wherein:
the first pixel includes a first sub-pixel including a first circuit part, a second sub-pixel including a second circuit part, a third sub-pixel including a third circuit part, and a fourth sub-pixel including a fourth circuit part,
the second pixel includes a first sub-pixel a first prime circuit part, a second sub-pixel including a second prime circuit part, a third sub-pixel including a third prime circuit part, and a fourth sub-pixel including a fourth prime circuit part, and
the plurality of gate lines include a first gate line and a second gate line, the first gate line supplies a signal to the third and fourth circuit parts, the first prime and second prime circuit parts, and the second gate line supplies a signal to the first and second circuit parts, the third prime and fourth prime circuit parts.

14. The display panel of claim 13, wherein:
the first sub-pixel is a red sub-pixel, the second sub-pixel is a green sub-pixel, the third sub-pixel is a white sub-pixel, and the fourth sub-pixel is a blue sub-pixel.

15. A method for repairing a display panel, comprising:
a first operation of forming a first driving voltage line and a second driving voltage line spaced apart from each other with a pixel therebetween and a plurality of driving voltage connection patterns configured to connect the first and second driving voltage lines;
a second operation of forming a plurality of gate lines that intersect the first and second driving voltage lines, the plurality of gate lines including at least one gate line including an open portion; and
a third operation of separating at least one of the plurality of driving voltage connection patterns from the first and second driving voltage lines to thereby form a repair pattern configured to connect two ends of the at least one gate line disconnected by the open portion.

16. The method of claim 15, wherein the third operation includes a third-first operation of forming first cutting portions and second cutting portions in the first and second driving voltage lines, respectively, and
wherein, in the third-first operation,
a first dummy driving voltage line separated from the first driving voltage line between the first cutting portions is formed, and
a second dummy driving voltage line separated from the second driving voltage line between the second cutting portions is formed.

17. The method of claim 16, wherein:
the repair pattern contacts each of the first and second dummy driving voltage lines,
the at least one gate line overlaps the first and second dummy driving voltage lines at opposite sides with the open portion therebetween, and
the third operation includes a third-second operation of forming connection portions in regions in which the at least one gate line overlaps the first and second dummy driving voltage lines.

18. The method of claim 17, wherein in the third-second operation, the at least one gate line contacts the first and second dummy driving voltage lines at the respective connection portions.

19. A display panel, comprising:
a first driving voltage line and a second driving voltage line spaced apart from each other with at least one pixel therebetween;
a plurality of driving voltage connection patterns configured to connect the first and second driving voltage lines; and
a plurality of gate lines that intersect the first and second driving voltage lines,
wherein the number of gate lines disposed between every two adjacent driving voltage connection patterns of the plurality of driving voltage connection patterns is 2 or less.
